(19) United States
(12) Patent Application Publication
(10) Pub. No.: US 2025/0323183 A1
(43) Pub. Date: Oct. 16, 2025

(54) SEMICONDUCTOR DEVICE WITH SEAL RING STRUCTURE AND METHOD FOR FORMING THE SAME

(71) Applicant: Taiwan Semiconductor Manufacturing Co., Ltd., Hsinchu (TW)

(72) Inventors: Ke-Gang Wen, Hsinchu (TW); Chih Hsin Yang, Zhubei City (TW); Kuan-Hsun Wang, Hsinchu (TW); Tsung-Chieh Hsiao, Shetou Township (TW); Liang-Wei Wang, Hsinchu (TW); Dian-Hau Chen, Hsinchu (TW)

(21) Appl. No.: 19/247,597

(22) Filed: Jun. 24, 2025

Related U.S. Application Data
(63) Continuation of application No. 18/493,187, filed on Oct. 24, 2023.
(60) Provisional application No. 63/520,722, filed on Aug. 21, 2023.

(51) Int. Cl. H01L 23/00; H01L 21/78; H01L 23/544; H01L 23/58; H10D 30/01; H10D 64/01

(52) U.S. Cl. CPC H01L 23/564; H01L 21/78; H01L 23/544; H01L 23/585; H10D 30/014; H10D 64/017; H01L 2223/5446

(57) ABSTRACT

A method includes forming first nanostructures over a first region of a substrate; forming second nanostructures over a second region of the substrate; forming first gate structures around the first nanostructures; replacing the second nanostructures with isolation regions; and forming a seal ring over the substrate, wherein the seal ring is between the first region and the second region.

### PRIORITY CLAIM AND CROSS-REFERENCE

This application is a continuation of U.S. patent application Ser. No. 18/493,187, filed on Oct. 24, 2023, which claims the benefit of U.S. Provisional Application No. 63/520,722, filed on Aug. 21, 2023, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a plan view of a device die and seal ring therein, in accordance with some embodiments.

FIG. 2 illustrates a plan view of a device wafer with device dies and seal rings therein, in accordance with some embodiments.

FIGS. 3, 4, 5, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 14C, 15A, 15B, 15C, 16A, 16B, 16C, 17A, 17B, 17C, 18A, 18B, 18C, 19, and 20 illustrate various views of intermediate steps in the formation of device die, in accordance with some embodiments.

FIGS. 21, 22, 23, 24, 25, and 26 illustrate cross-sectional views of intermediate steps in the formation of isolation regions, in accordance with some embodiments.

FIG. 27 illustrates a plan view of a device die, in accordance with some embodiments.

FIG. 28 illustrates a cross-sectional view of a device die, in accordance with some embodiments.

FIGS. 29, 30, 31, 32, and 33 illustrate cross-sectional views of intermediate steps in the formation of isolation regions, in accordance with some embodiments.

FIG. 34 illustrates a plan view of a device die, in accordance with some embodiments.

FIGS. 35, 36, and 37 illustrate cross-sectional views of intermediate steps in a singulation process, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, buffer region between a seal ring and a scribe region is formed comprising isolation structures and/or epitaxial structures. By forming the isolation structures in the buffer region, the processing may be improved such that a smaller buffer region may be used, thus increasing device density. For example, the presence of the isolation regions can improve the planarity of the buffer region. Further, the buffer region may be formed without metal features, which can improve plasma dicing of the scribe region.

The disclosed nanostructure field effect transistors (NSFETs) embodiments could also be applied to other nanostructure devices such as nanosheet devices, nanowire devices, gate-all-around (GAA) devices, nano-FETs, or the like. Embodiments are described below in a particular context, a die comprising nano-FETs. Various embodiments may be applied, however, to dies comprising other types of transistors (e.g., fin field effect transistors (FinFETs), planar transistors, or the like) in lieu of or in combination with the NSFETs. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

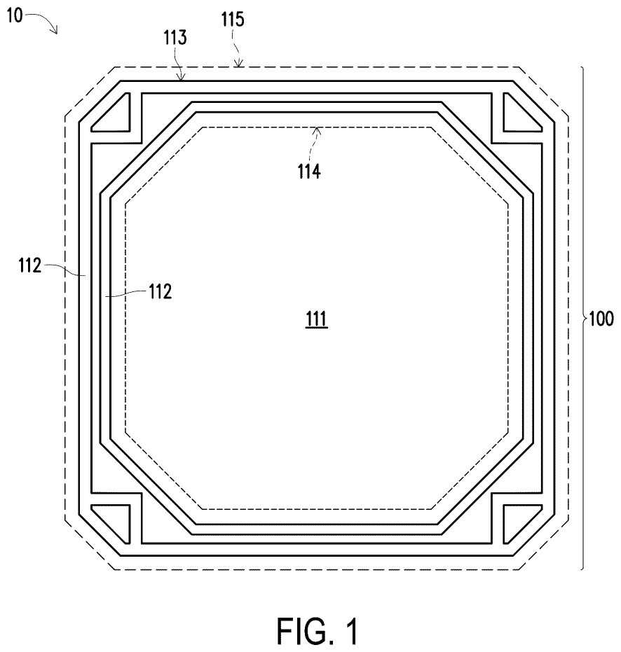

FIG. 1 illustrates a top view of a device die 100, in accordance with some embodiments. The device die 100 may be formed on a wafer 10, described in greater detail below. The device die 100 includes one or more seal rings 112 formed near the perimeter (e.g., near the edges) of the device die 100. Seal rings 112 may provide protection for the features of device die 100 from water, chemicals, residue, and/or contaminants that may be present during the processing of device die 100. In some embodiments, the seal ring 112 includes one or more outer seal rings 112 encircling one or more inner seal rings 112. In other embodiments, only one seal ring 112 is present. Accordingly, the term “seal ring 112” used herein may refer to a structure comprising a single seal ring or a structure comprising multiple seal rings.

The seal ring 112 may be formed along a periphery of the device die 100 and may be a continuous structure formed to surround a device region 111 of the device die 100. The seal ring 112 is formed in a seal ring region 113 that encircles a device region 111 of the device die 100, in some embodiments. The device region 111 is used for forming functional circuits, integrated circuit devices, and/or interconnect structures, described in greater detail below. In some embodiments, the seal ring 112 is formed using the same conductive materials and process steps as conductive features within the device region 111. In some embodiments, the seal ring region 113 contains dummy devices, which may or may not be electrically isolated from the seal ring 112.

In some embodiments, the seal ring region 113 is separated from the device region 111 by an inner buffer region 114. In some embodiments, the inner buffer region 114 contains dummy devices and/or dummy conductive features. Separating the device region 111 from the seal ring region 113 by the inner buffer region 114 can reduce the risk of damage to features in the device region 111 and also improve processing of the device region 111.

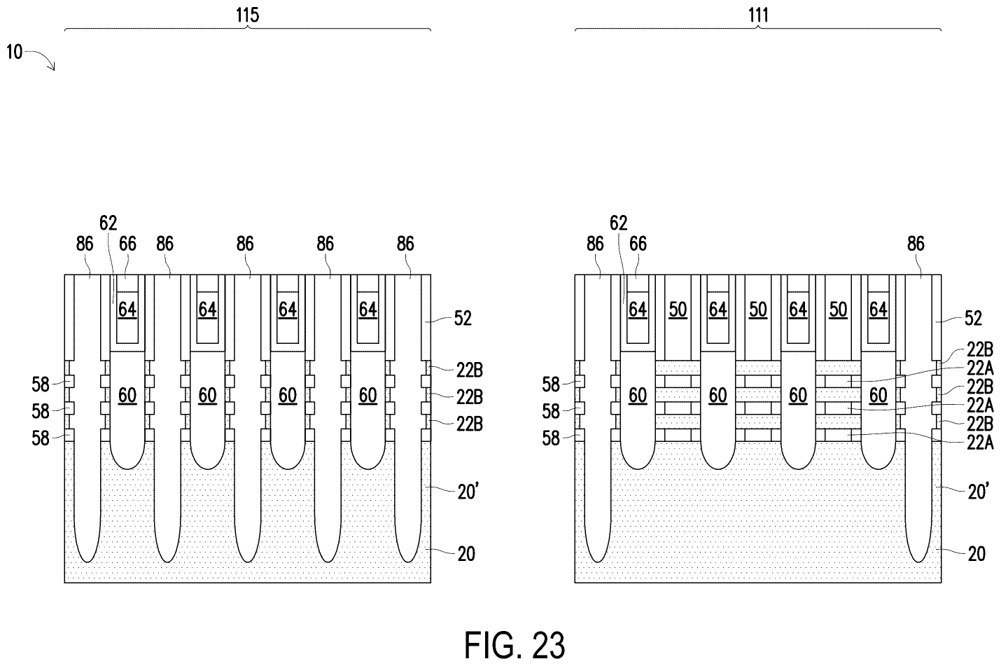

In some embodiments, the seal ring region 113 is encircled by an outer buffer region 115. The outer buffer region 115 separates the seal ring 112 from the scribe region 116 (described below), and reduces the risk of damage to the seal ring 112 during singulation. For example, in some embodiments, the outer buffer region 115 protects the seal ring 112 from damage when a plasma dicing process is used to singulate the device dies 100. In some embodiments, the outer buffer region 115 is free of conductive features (e.g., metal features), which can allow for improved plasma dicing. In some embodiments, the outer buffer region 115 may contain dummy devices or isolation regions (e.g., isolation regions 86, see FIG. 23), which can reduce topographical effects, improve planarity, improve processing, allow for the outer buffer region 115 to have a smaller width, and reduce the risk of damage to the seal ring 112 during singulation. In some cases, portions of the outer buffer region 115 may be removed during the singulation process.

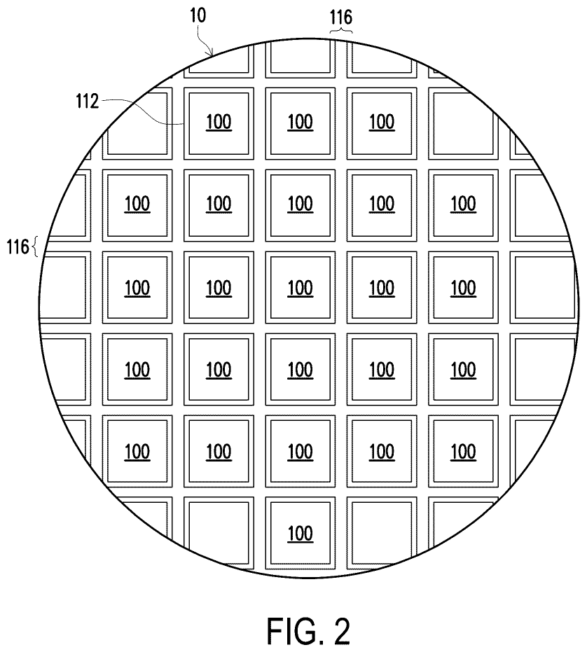

FIG. 2 illustrates a plan view of a wafer 10 containing multiple device dies 100, in accordance with some embodiments. The wafer 10 and/or device dies 100 may be similar to those described elsewhere herein. The device dies 100 are separated by scribe regions 116 that are at least partially removed during the singulation process to form individual device dies 100. For example, the scribe regions 116 may be removed using a sawing process, a plasma dicing process, or the like. As shown in FIG. 2, each device die 100 comprises a seal ring 112 around its perimeter.

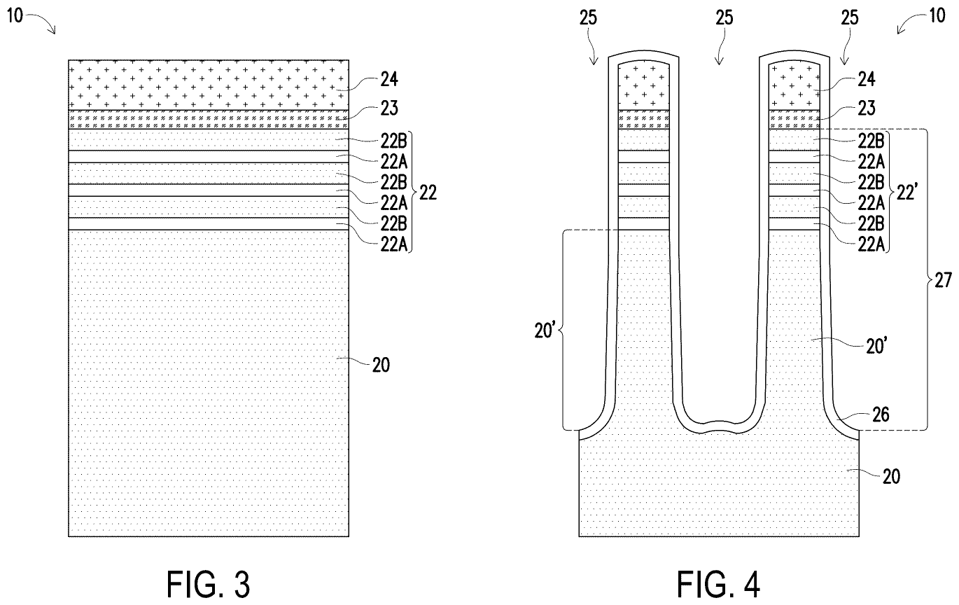

FIGS. 3 through 28 illustrate intermediate steps in the formation of isolation regions 86 for an outer buffer region 115 of a seal ring 112, in accordance with some embodiments. The process steps shown in FIGS. 3 through 18C may be performed in the device region 111 and the outer buffer region 115, in some embodiments. The process steps may also be performed in the seal ring region 113 and/or the inner buffer region 114, in some embodiments. First referring to FIG. 3, a cross-sectional view of wafer 10 is shown. Wafer 10 may be similar to the wafer 10 described for FIGS. 1-2, in some cases. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used.

In accordance with some embodiments, multilayer stack 22 is formed through a series of deposition processes for depositing alternating materials. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises silicon; germanium; a compound semiconductor including silicon carbide, gallium arsenide, gallium phosphide, indium phosphide, indium arsenide, and/or indium antimonide; an alloy semiconductor including silicon germanium (SiGe), gallium arsenide phosphide, aluminum indium arsenide, aluminum gallium arsenide, gallium indium arsenide, gallium indium phosphide, and/or gallium indium arsenide phosphide; the like, or combinations thereof. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises silicon; germanium; a compound semiconductor including silicon carbide, gallium arsenide, gallium phosphide, indium phosphide, indium arsenide, and/or indium antimonide; an alloy semiconductor including silicon germanium (SiGe), gallium arsenide phosphide, aluminum indium arsenide, aluminum gallium arsenide, gallium indium arsenide, gallium indium phosphide, and/or gallium indium arsenide phosphide; the like, or combinations thereof, in which the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, pad layer 23 and hard mask 24 are deposited over multilayer stack 22. Pad layer 23 (sometimes referred to as a sacrificial layer) may be formed of a compound comprising silicon and another material(s) selected from carbon, oxide, nitrogen, or combinations thereof. Hard mask 24 may be formed of or comprise silicon nitride.

Referring to FIG. 4, hard mask 24 and pad layer 23 are patterned. Next, multilayer stack 22 and a portion of the underlying substrate 20 are patterned in an etching process(es), so that trenches 25 are formed. Trenches 25 extend into substrate 20. The remaining portions of multilayer stacks are referred to as multilayer stacks 22′ hereinafter. Underlying multilayer stacks 22′, some portions of substrate 20 are left, and are referred to as substrate strips 20′ or fins 20′ hereinafter. Multilayer stacks 22′ include semiconductor layers 22A and 22B. Semiconductor layers 22A are alternatively referred to as sacrificial layers, and semiconductor layers 22B are alternatively referred to as nanostructures hereinafter. The portions of multilayer stacks 22′ and the underlying substrate strips 20′ are collectively referred to as semiconductor strips 27.

In above-illustrated embodiments, the nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the structure.

FIGS. 4, 5, 6A, 6B, and 6C illustrate the formation of isolation regions 30, which are also referred to as Shallow Trench Isolation (STI) regions throughout the description. Referring to FIG. 4, dielectric liner 26, which may be a conformal dielectric layer, is deposited. Dielectric liner 26 may comprises silicon oxide, silicon nitride, or the like, and may be formed using, for example, ALD, High-Density Plasma Chemical Vapor Deposition (HDPCVD), CVD, or the like.

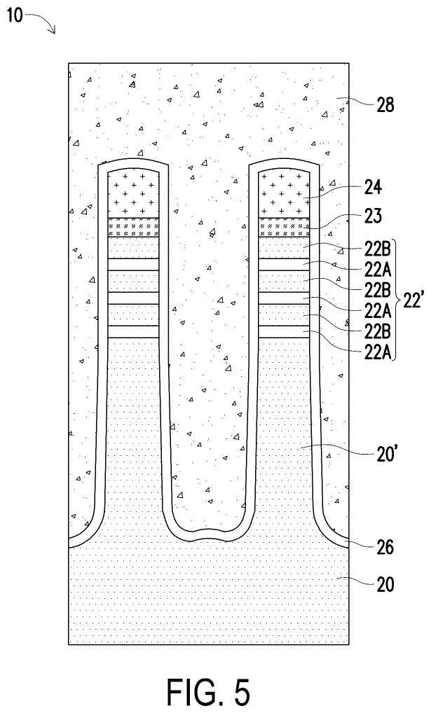

Next, referring to FIG. 5, dielectric material 28 is deposited over dielectric liner 26. Dielectric material 28 may comprise silicon oxide or other dielectric material comprising carbon, nitrogen, or the like, and may be formed using Flowable Chemical Vapor Deposition (FCVD), spin-on coating, HDPCVD, ALD, CVD, or the like.

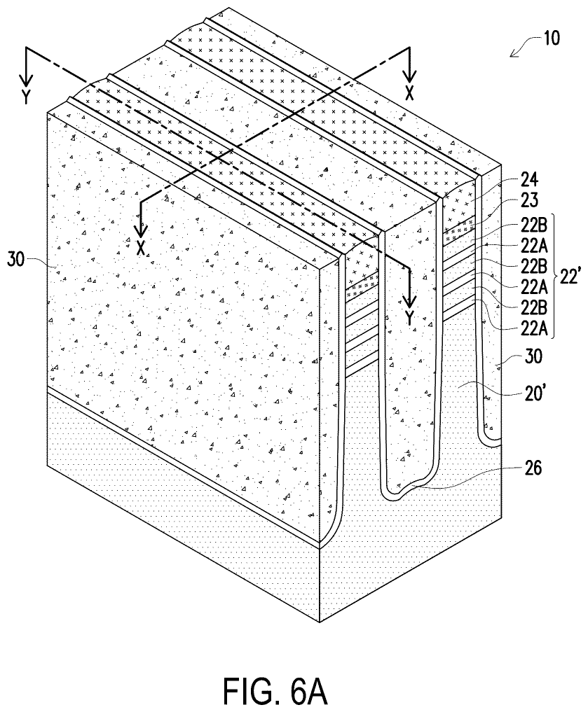

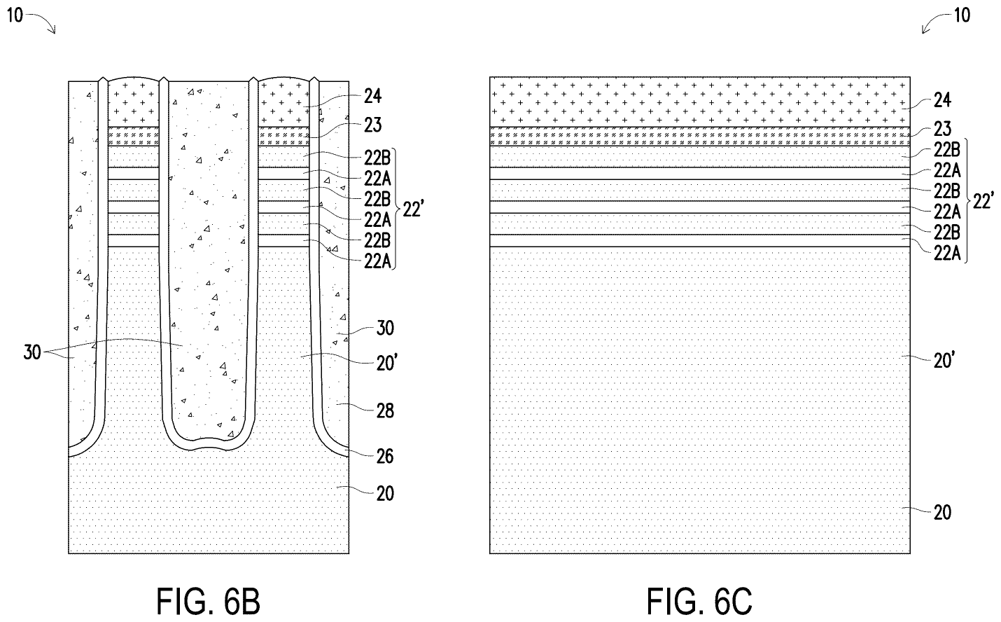

The subsequent figure numbers in FIGS. 6A, 6B, and 6C through FIGS. 18A, 18B, and 18C may have the corresponding numbers followed by letter A, B, or C. The Figures whose reference numbers include letter A show perspective views. The Figures whose reference numbers include letter B illustrate the cross-sectional views obtained from the vertical plane X-X (FIG. 6A) in the corresponding perspective view. The Figures whose reference numbers include letter C illustrate the cross-sectional views obtained from the vertical plane Y-Y (FIG. 6A) in the corresponding perspective view.

Referring to FIGS. 6A, 6B, and 6C, a planarization process such as a Chemical Mechanical Polish (CMP) process or a mechanical grinding process is performed to polish and level the top surface of the dielectric material 28 and dielectric liner 26, and the remaining portions of dielectric material 28 and dielectric liner 26 are STI regions 30. In the planarization process, either hard mask 24 or pad layer 23 may be used as a polish stop layer.

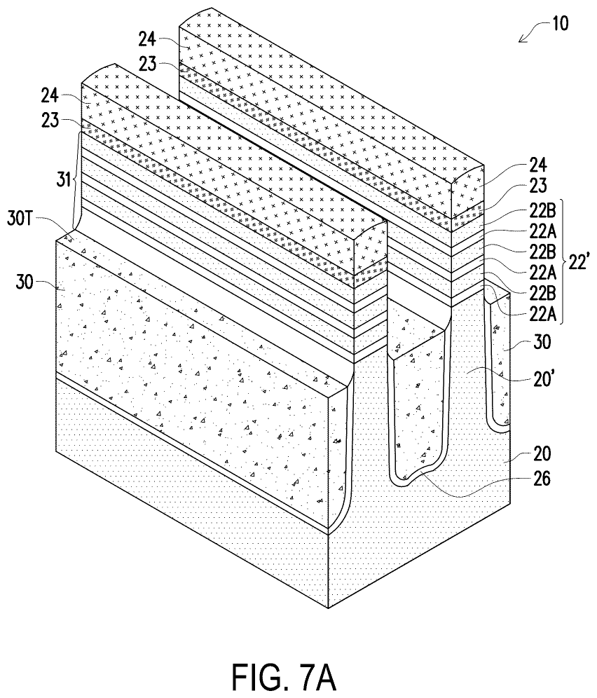

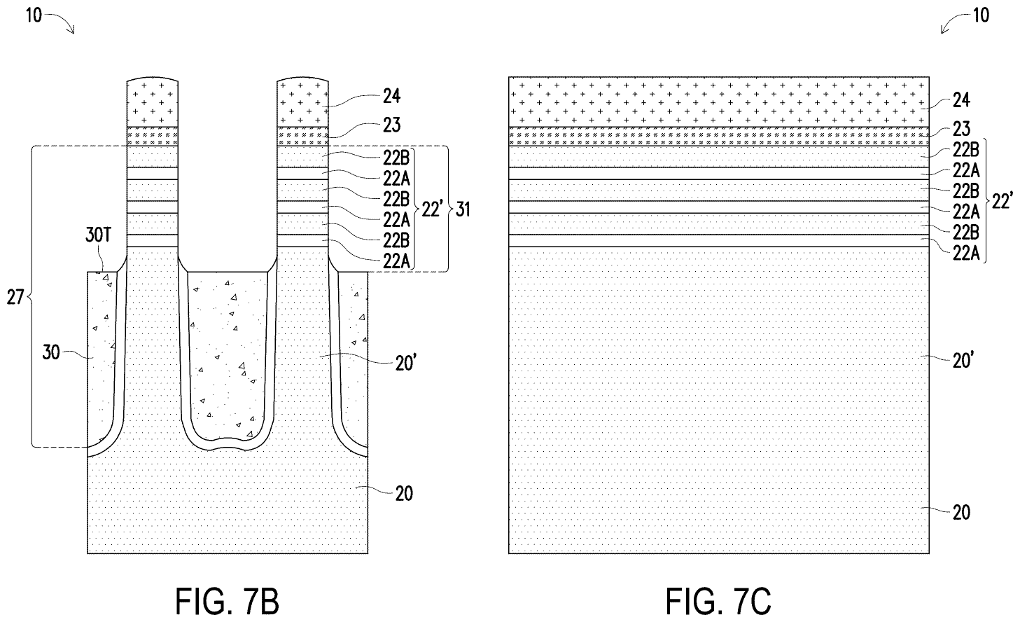

Referring to FIGS. 7A, 7B, and 7C, STI regions 30 are recessed, so that the top portions of semiconductor strips 27 (FIG. 7B) protrude higher than the top surfaces 30T of the remaining portions of STI regions 30 to form protruding fins 31. Protruding fins 31 include multilayer stacks 22′ and the top portions of substrate strips 20′. The recessing of STI regions 30 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 30 is performed through a wet etching process. The etching chemical may include HF, for example.

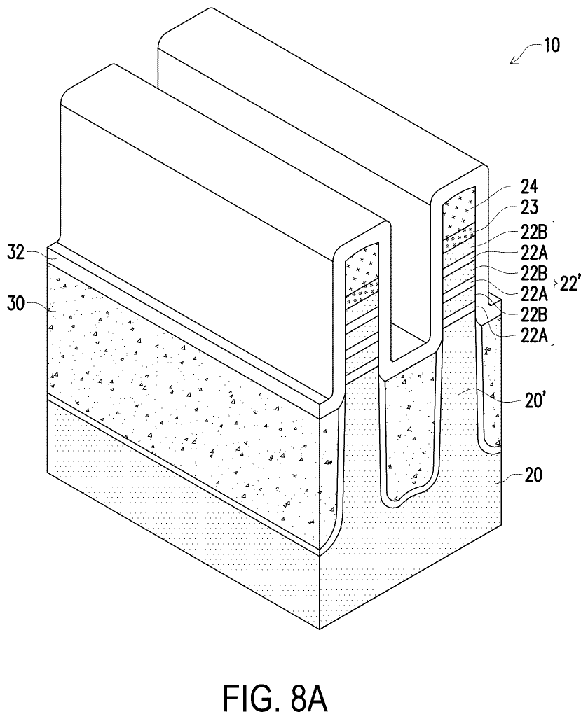

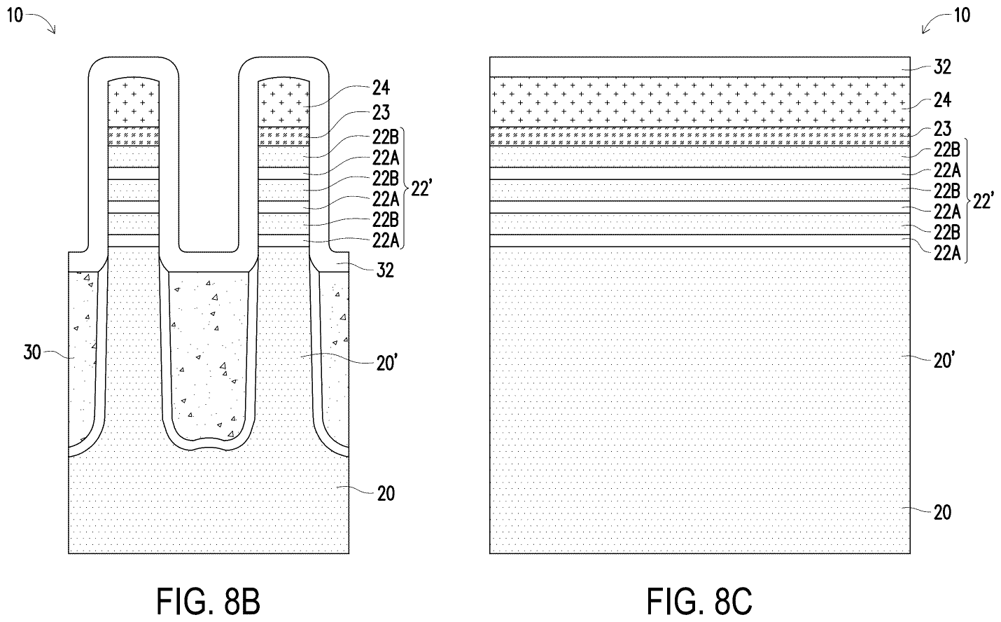

Referring to FIGS. 8A, 8B, and 8C, cladding SiGe layer 32 is deposited. Cladding SiGe layer 32 may be formed through a conformal deposition process such as ALD, CVD, or the like. In accordance with alternative embodiments, cladding SiGe layer 32 is not formed. An anisotropic etching process may then be performed to remove horizontal portions of cladding SiGe layer 32, leaving the vertical portions of cladding SiGe layer 32.

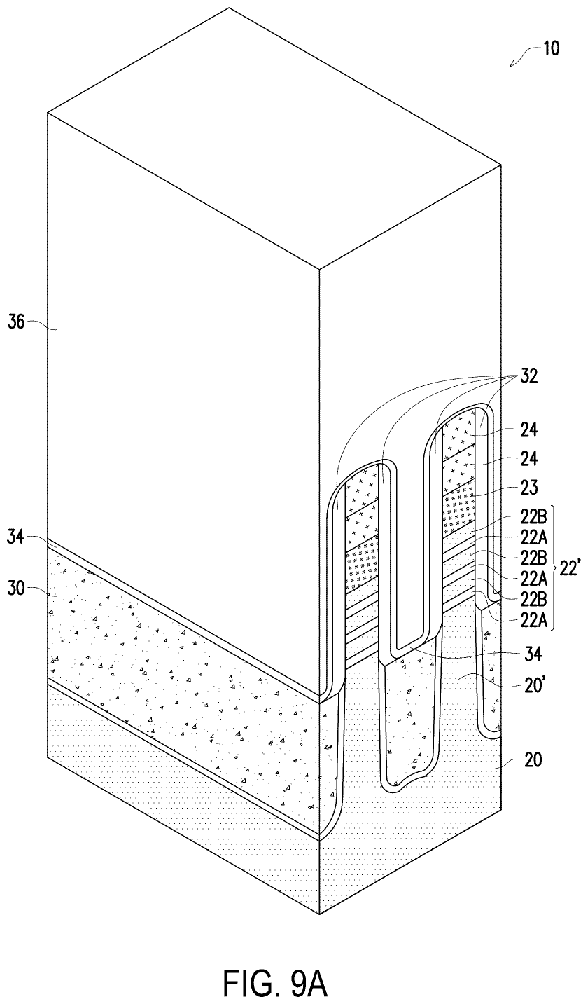

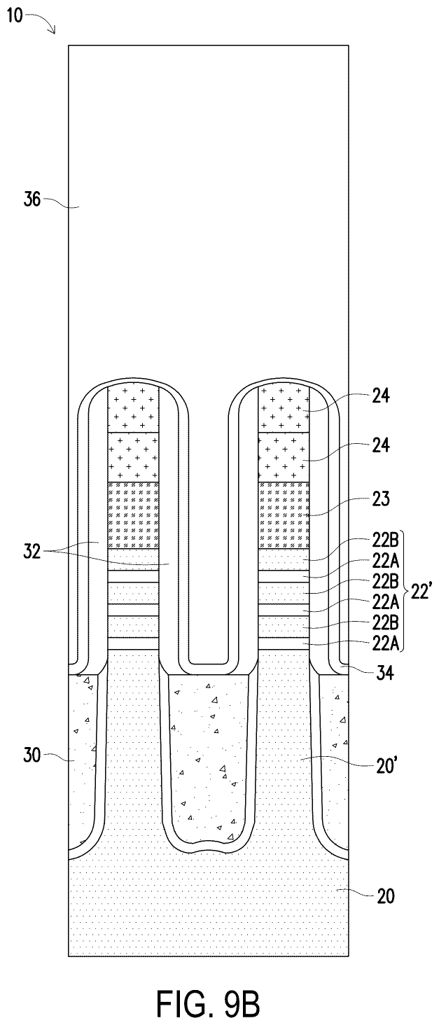

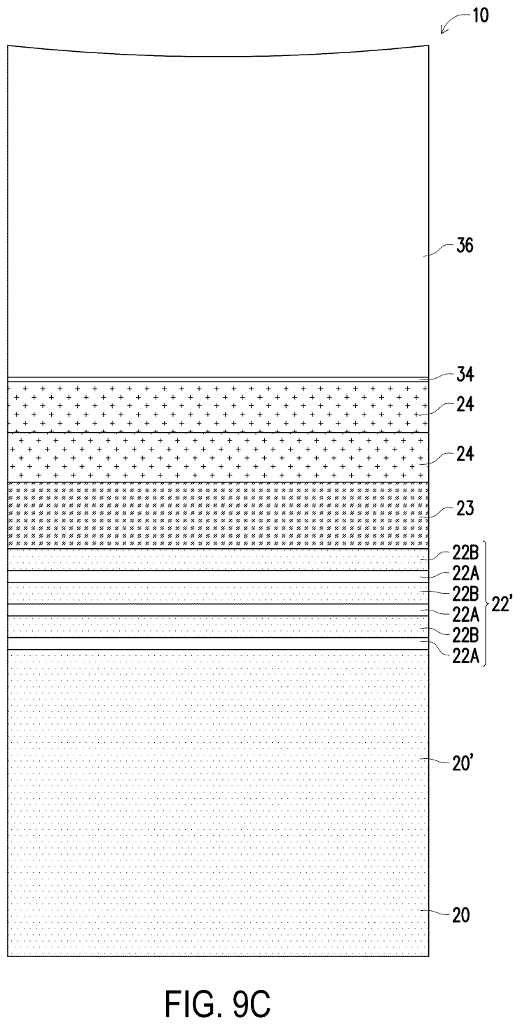

In FIGS. 9A, 9B, and 9C, dielectric liner 34 is formed, followed by the deposition of dielectric layer 36. Dielectric liner 34 may be formed of or comprise, for example, silicon carbo-nitride, silicon oxycarbide, silicon nitride, or the like, and may be formed through a conformal deposition process such as ALD, CVD, or the like. Dielectric layer 36 may be formed of or comprise silicon oxide, and may be formed through a deposition process, spin-on coating, or the like.

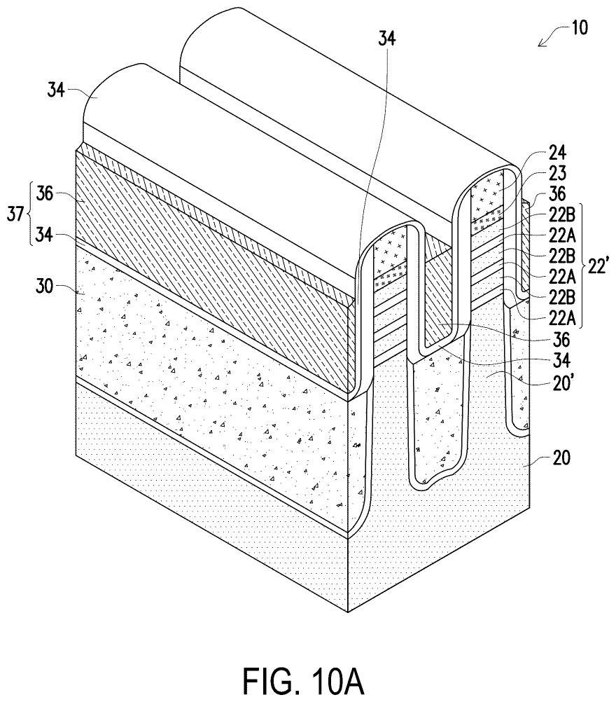

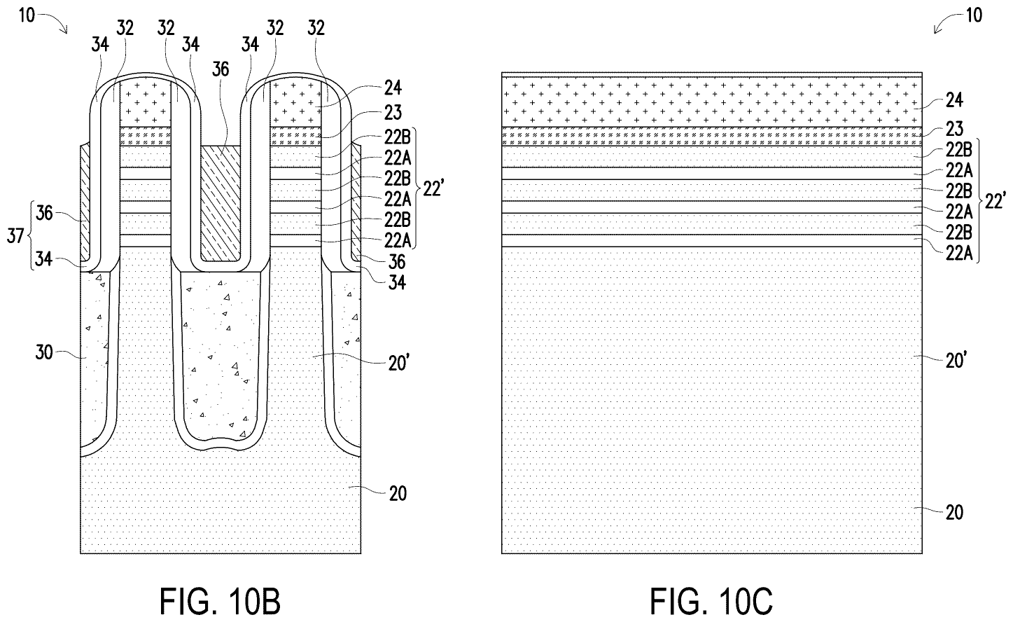

FIGS. 10A, 10B, and 10C illustrate the etch-back of dielectric layer 36 and dielectric liner 34. The remaining dielectric liner 34 and dielectric layer 36 are in the gaps between neighboring multilayer stacks 22′, and are collectively referred to as dielectric regions 37. In accordance with some embodiments, the top surface of dielectric layer 36 is level with or lower than the top ends of multilayer stacks 22′. By controlling etching processes, the top ends of dielectric liner 34 may be higher than the top surface of dielectric layer 36 in accordance with some embodiments.

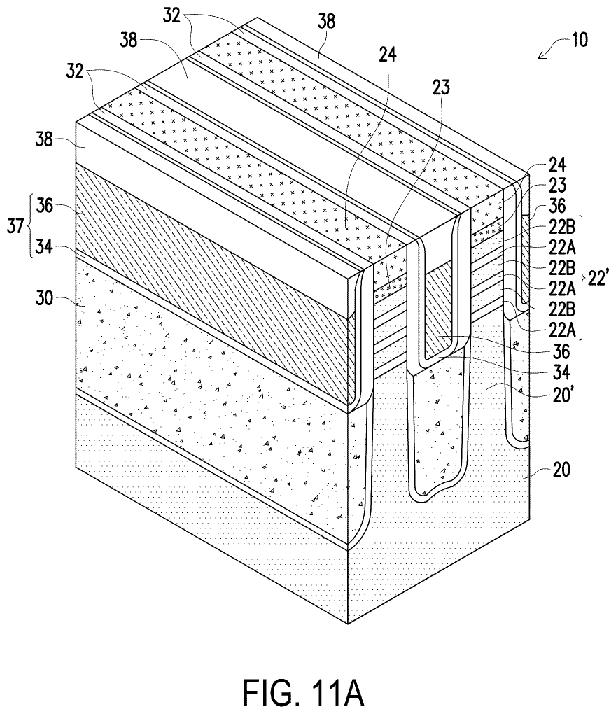

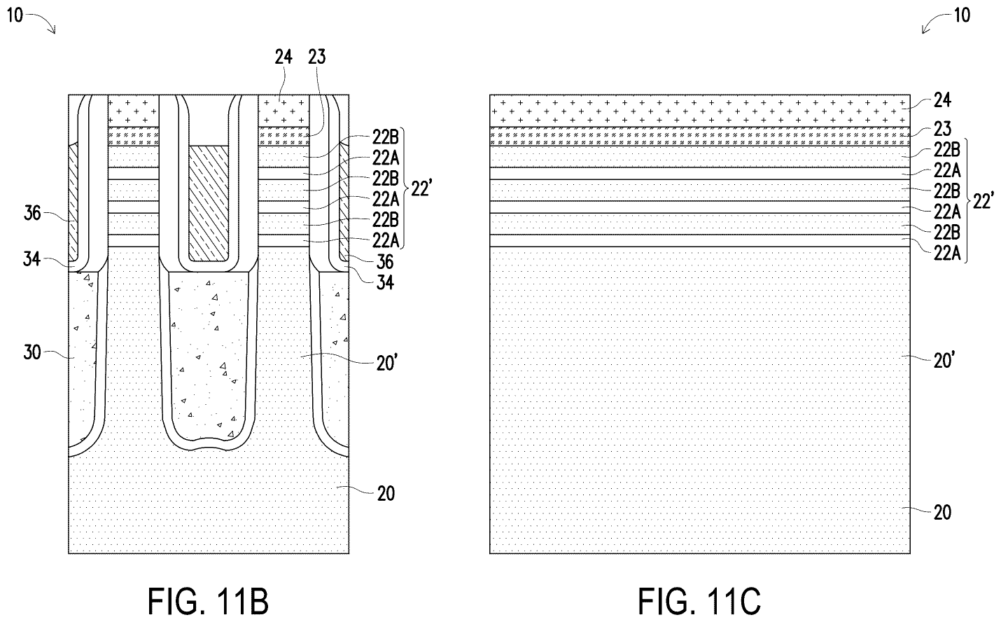

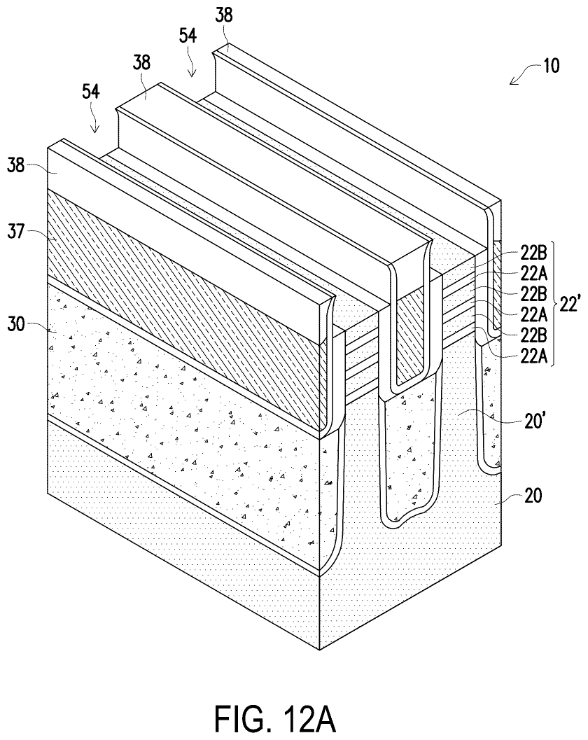

FIGS. 11A, 11B, and 11C illustrate the formation of high-k dielectric regions 38. In accordance with some embodiments, dielectric region 38 is deposited through High-density Plasma Chemical Vapor Deposition (HDPCVD), PECVD, ALD, CVD, or the like. The material of dielectric region 38 may be selected from hafnium oxide, zirconium oxide, aluminum oxide, aluminum nitride, titanium nitride, silicon oxide, silicon nitride, silicon oxynitride, silicon oxycarbonitride, or the like. A planarization process is then performed to level the top surfaces of dielectric regions 38 with hard masks 24 in accordance with some embodiments.

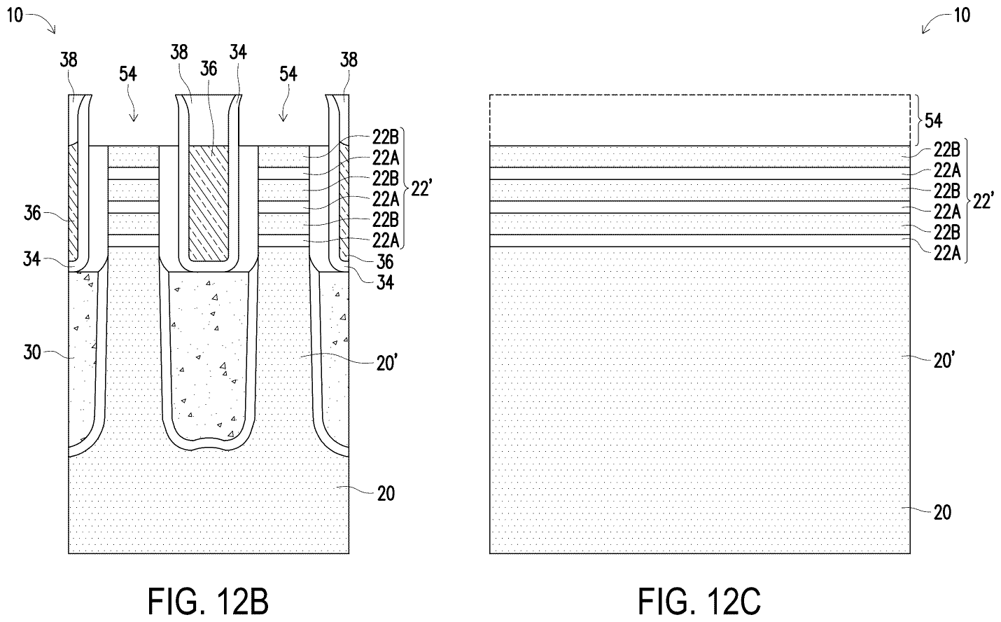

Next, hard masks 24 and pad layers 23 are removed, for example, in dry etching processes and/or wet etching processes. Accordingly, as shown in FIGS. 12A, 12B, and 12C, recesses 54 are formed between high-k dielectric regions 38, which may protrude higher than multilayer stacks 22′.

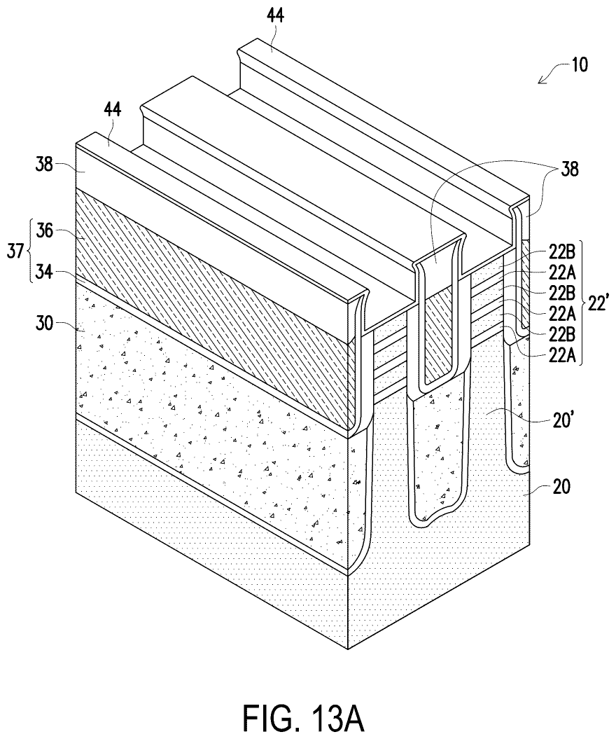

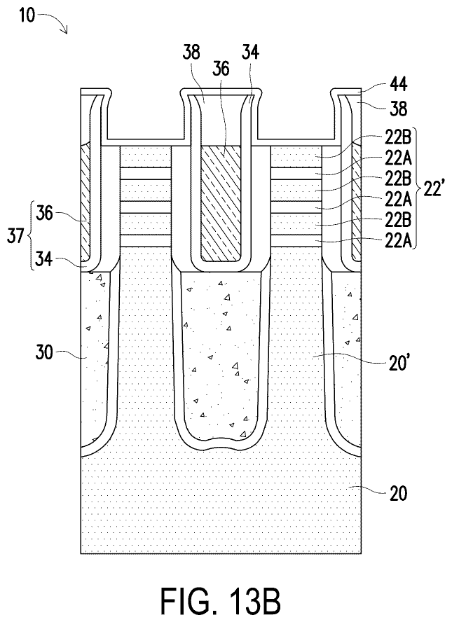

FIGS. 13A and 13B illustrate the formation of dummy gate dielectric layer 44, which is formed as a conformal layer. In accordance with some embodiments, dummy gate dielectric layer 44 is deposited, for example, using a conformal deposition process such as ALD, CVD, or the like. Dummy gate dielectric layer 44 may be formed of or comprise silicon oxide in accordance with some embodiments. Dummy gate dielectric layer 44 extends into recesses 54, and extends on the top surfaces of high-k dielectric regions 38.

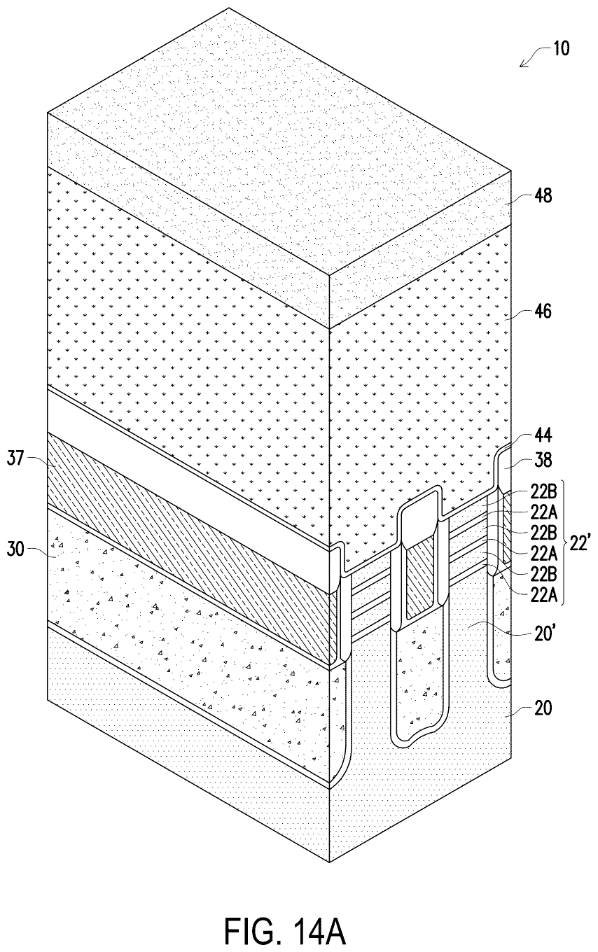

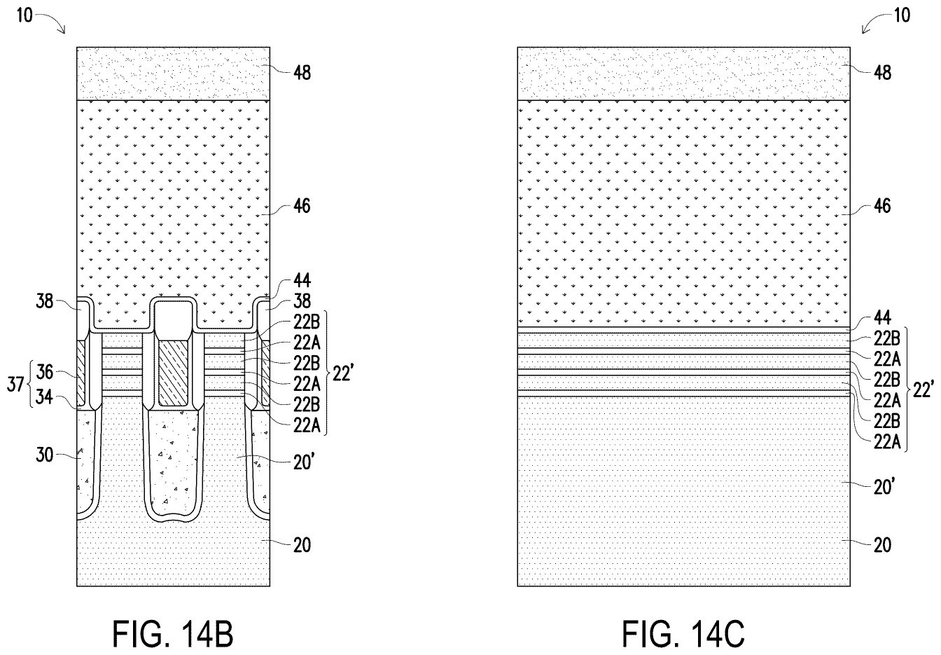

FIGS. 14A, 14B, and 14C illustrate the deposition of dummy gate electrode layer 46. In accordance with some embodiments, dummy gate electrode layer 46 is formed of or comprises polysilicon, amorphous silicon, or the like. Hard mask layer 48 is also formed over dummy gate electrode layer 46. Hard mask layer 48 may be formed of silicon nitride, silicon oxide, silicon carbonitride, silicon oxycarbonitride, or the like, or multilayers thereof.

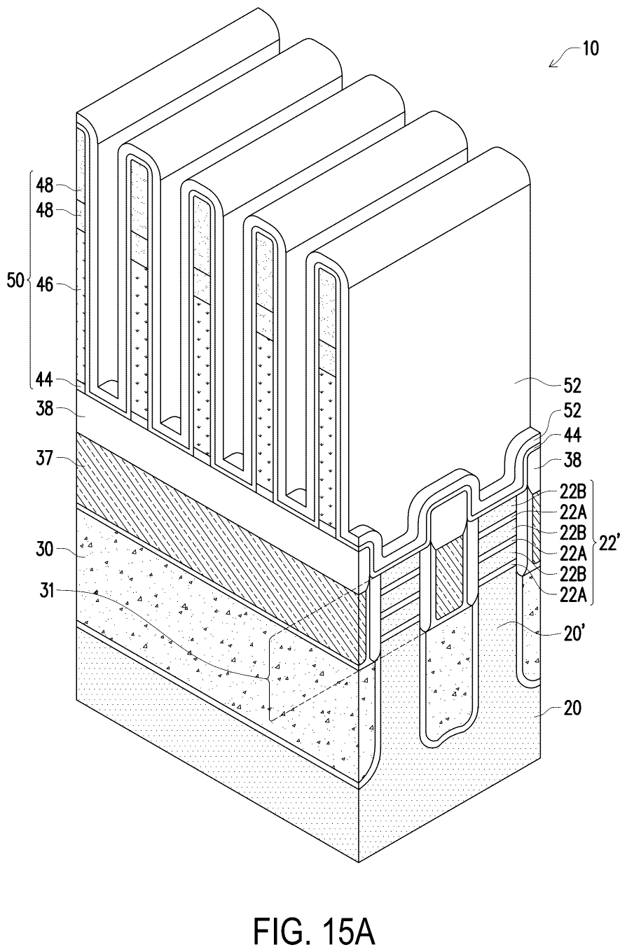

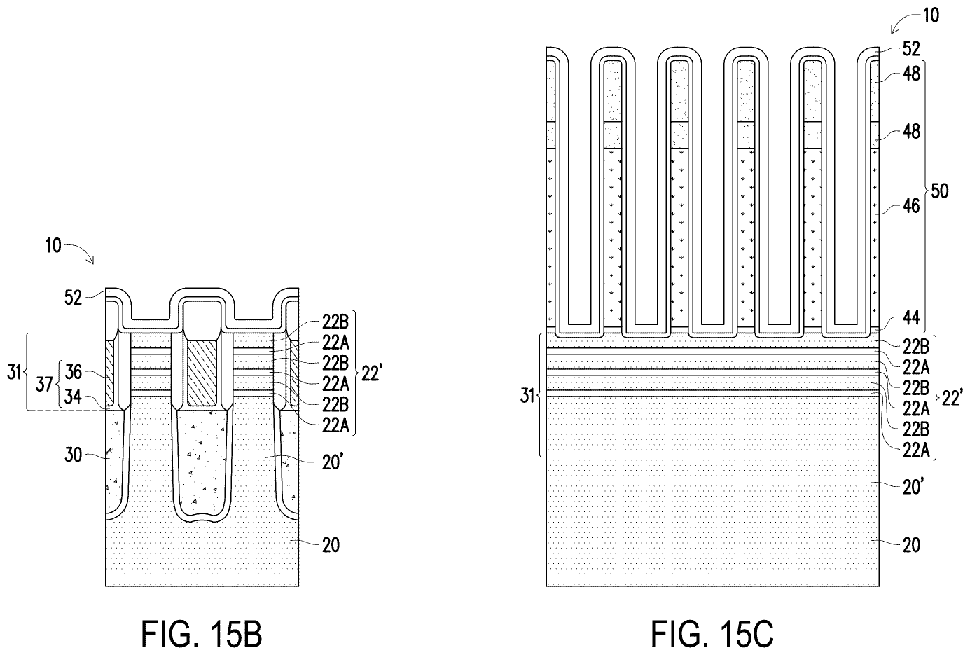

Next, as shown in FIGS. 15A, 15B, and 15C, hard mask layer 48, dummy gate electrode layer 46, and dummy gate dielectric layer 44 are patterned in etching processes, hence forming dummy gate stacks 50. The remaining portions of hard mask layer 48, dummy gate electrode layer 46, and dummy gate dielectric layer 44 are referred to as hard masks 48, dummy gate electrodes 46, and dummy gate dielectrics 44, respectively.

Next, gate spacer layer 52 is deposited, for example, through a conformal deposition process such as ALD, CVD, or the like. In accordance with some embodiments, gate spacer layer 52 is formed of a dielectric material such as silicon nitride, silicon oxide, silicon carbonitride, silicon oxynitride, silicon oxycarbonitride, or the like, and may have a single-layer structure or a multilayer structure including a plurality of dielectric layers. After the deposition process, an anisotropic etching process(es) may be performed to etch the horizontal portions of gate spacer layer 52, leaving vertical portions of gate spacer layer 52 unremoved. The remaining portions of the dielectric layer(s) are referred to as gate spacers 52. In subsequent figures, gate stacks 50 are shown, while dummy gate dielectric layer 44 and dummy gate electrode layer 46 may not (or may) be shown separately.

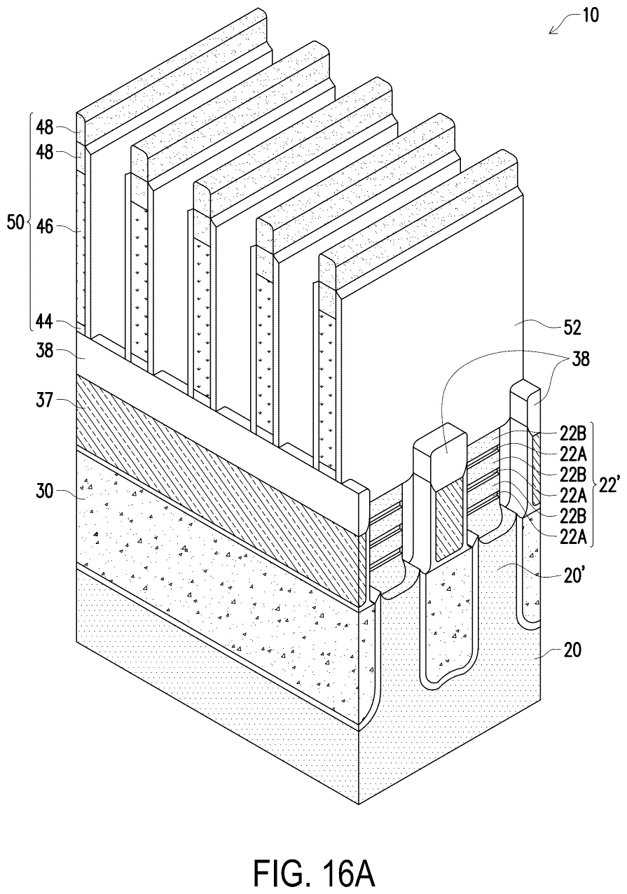

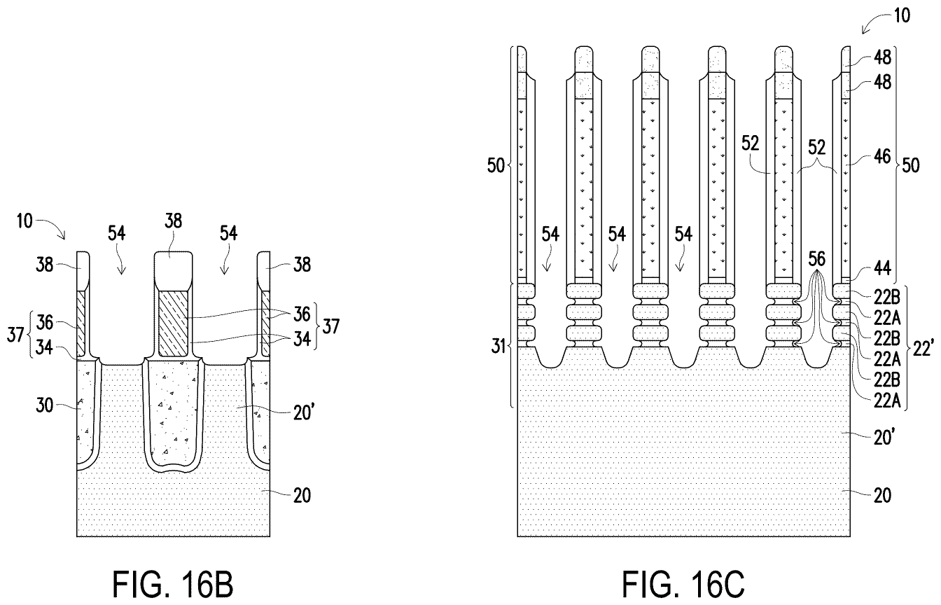

FIGS. 16A, 16B, and 16C illustrate a resulting structure after the formation of gate spacers 52, which are in the plane shown in FIGS. 16A and 16C. Next, the portions of protruding fins 31 (FIGS. 15A, 15B, and 15C) that are not directly underlying dummy gate stacks 50 and gate spacers 52 are recessed through an etching process to form recesses 54, which are between the un-etched portions of protruding fins 31. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 54 are at least level with, or may be lower than (as shown in FIG. 16C), the bottoms of multilayer semiconductor stacks 22′. The etching may be anisotropic, so that the sidewalls of multilayer semiconductor stacks 22′ facing recesses 54 are vertical and straight.

After the formation of recesses 54, as also shown in FIG. 16C, sacrificial semiconductor layers 22A are laterally recessed to form lateral recesses 56, which are recessed from the edges of the respective overlying and underlying nanostructures 22B. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). In accordance with alternative embodiments, the lateral recessing of sacrificial semiconductor layers 22A is performed through an isotropic dry etching process or a combination of a dry etching process and a wet etching process.

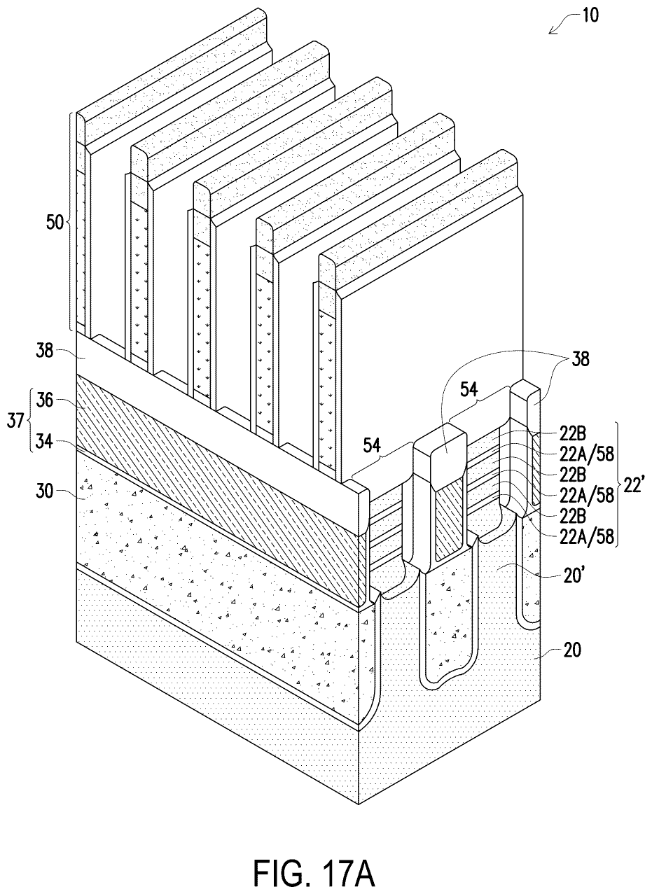

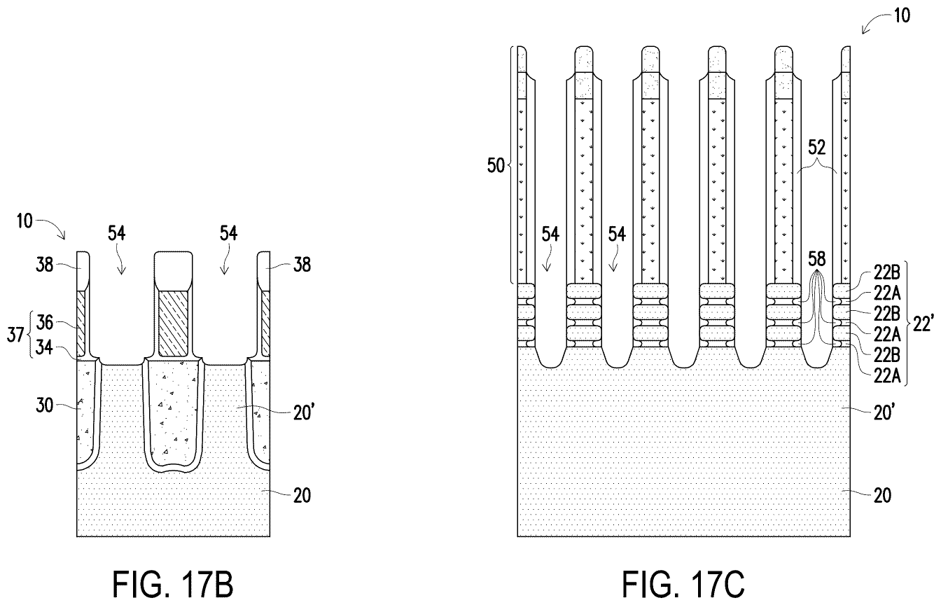

FIGS. 17A, 17B, and 17C illustrate the formation of inner spacers 58. The formation process incudes depositing a spacer layer extending into recesses 56, and performing an etching process to remove the portions of inner spacer layer outside of recesses 56, thus leaving inner spacers 58 in recesses 56. Inner spacers 58 may be formed of or comprise silicon oxycarbonitride, silicon oxynitride, silicon oxycarbide, silicon carbonitride, or the like. In accordance with some embodiments, the etching of the spacer layer may be performed through a wet etching process, in which the etching chemical may include H₂SO₄, diluted HF, ammonia solution (NH₄OH, ammonia in water), or the like, or combinations thereof.

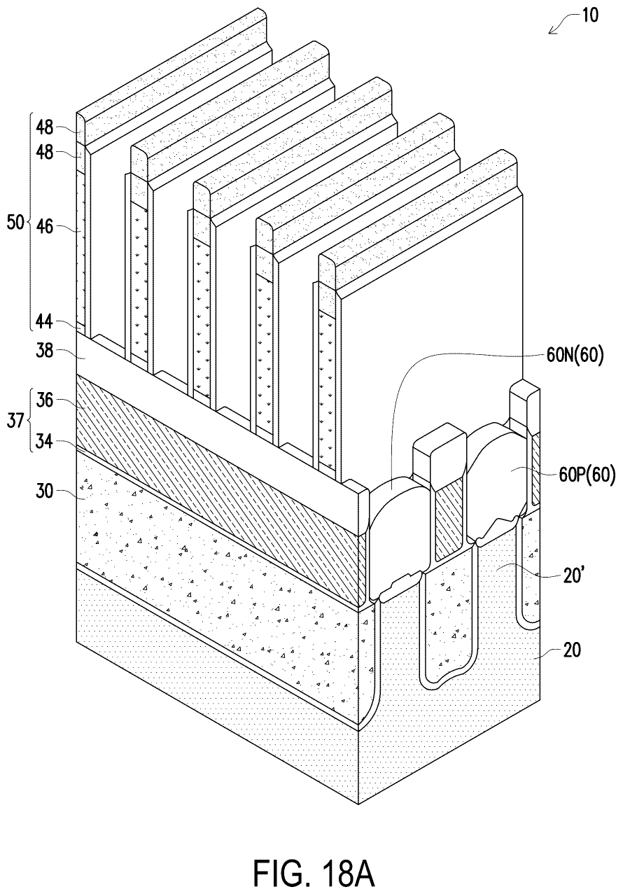

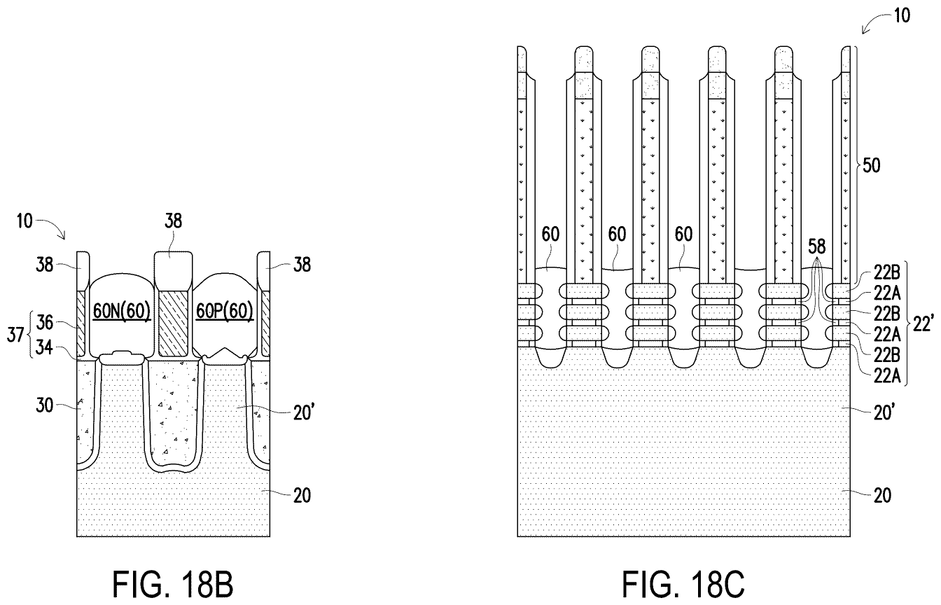

Referring to FIGS. 18A, 18B, and 18C, epitaxial source/drain regions 60 are formed in recesses 54. Source/drain region(s) may refer to a source or a drain, individually or collectively dependent upon the context. In accordance with some embodiments, the source/drain regions 60 may exert stress on the nanostructures 22B, which are used as the channels of the corresponding nanostructure transistors, thereby improving performance. When the resulting transistors are n-type transistors, epitaxial source/drain regions 60 are formed to be n-type by doping an n-type dopant. For example, the n-type source/drain regions 60 may be formed of or comprise silicon phosphorous (SiP), silicon carbon phosphorous (SiCP), or the like. When the resulting transistors are p-type transistors, epitaxial source/drain regions 60 are formed to be p-type by doping a p-type dopant. For example, the p-type source/drain regions 60 may be formed of or comprise silicon germanium boron (SiGeB), silicon boron (SiB), or the like. FIGS. 17A and 17B schematically illustrate an n-type epitaxial source/drain region 60N and a p-type epitaxial source/drain regions 60P as an example. In some cases, the epitaxial source/drain regions 60 formed in the outer buffer region 115 may reduce stress during a singulation process, stress due to the seal ring 112, or stress from other sources. Reducing stress by forming epitaxial source/drain regions 60 in the outer buffer region 115 can improve yield and improve device reliability.

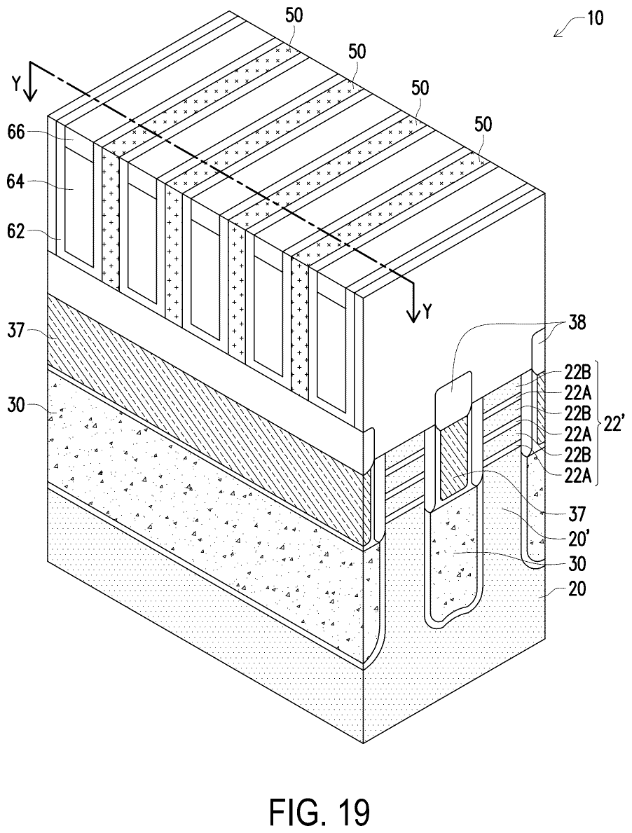

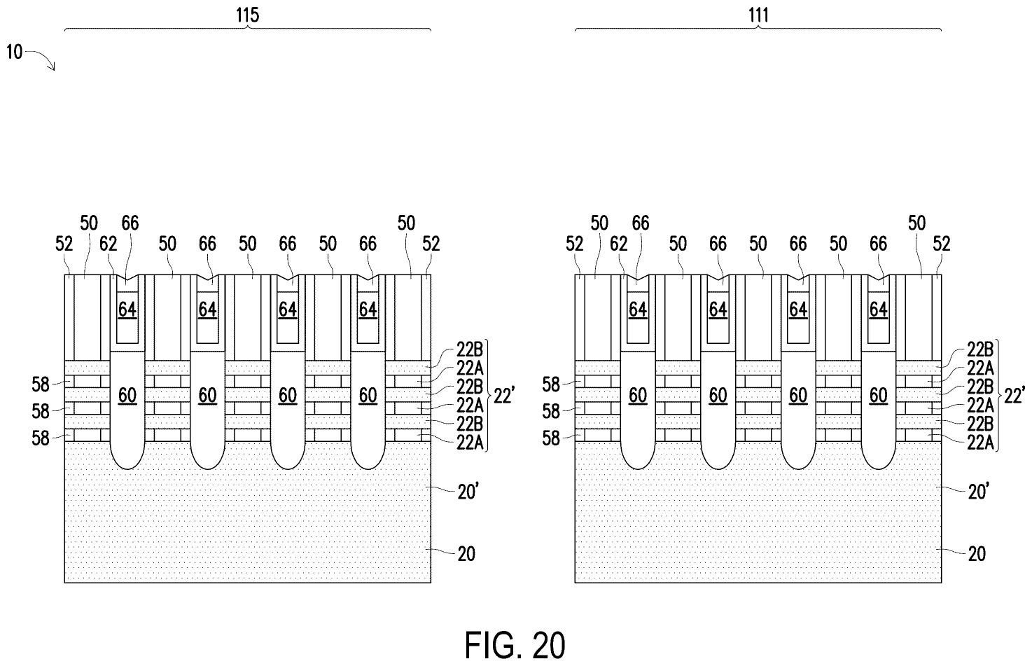

FIGS. 19 through 28 illustrate intermediate steps in the formation of a seal ring 112, in accordance with some embodiments. FIG. 19 illustrates a perspective view following the step shown in FIGS. 18A-18C. FIGS. 20 through 26 illustrate cross-sectional views obtained from the vertical plane Y-Y described previously and as also indicated in FIG. 19 for reference. Each of FIGS. 20 through 26 illustrates a cross-sectional view of an outer buffer region 115 and a cross-sectional view of a device region 111 of the structure in which devices (e.g., NSFETs or other devices) are formed. The process steps shown for the outer buffer region 115 may also be performed for the seal ring region 113 and/or the inner buffer region 114, in some embodiments.

FIGS. 19 and 20 illustrate views of the structure after the formation of Contact Etch Stop Layer (CESL) 62 and Inter-Layer Dielectric (ILD) 64. CESL 62 may be formed of silicon oxide, silicon nitride, silicon carbonitride, or the like, and may be formed using CVD, ALD, or the like. ILD 64 may include a dielectric material formed using, for example, FCVD, spin-on coating, CVD, or any other suitable deposition method. ILD 64 may be formed of an oxygen-containing dielectric material, which may include a silicon-oxide, Phospho-Silicate Glass (PSG), Boro-Silicate Glass (BSG), Boron-Doped Phospho-Silicate Glass (BPSG), Undoped Silicate Glass (USG), or the like. The formation of CESL 62 and ILD 64 include depositing a conformal CESL 62, depositing ILD 64, and performing a planarization process. In accordance with some embodiments, hard masks 66 are formed, and may be formed of or comprise silicon nitride, silicon oxynitride, silicon oxycarbide, or the like. The formation process may include recessing ILD 64 to form recesses, depositing the corresponding dielectric material into the recesses, and performing a planarization process.

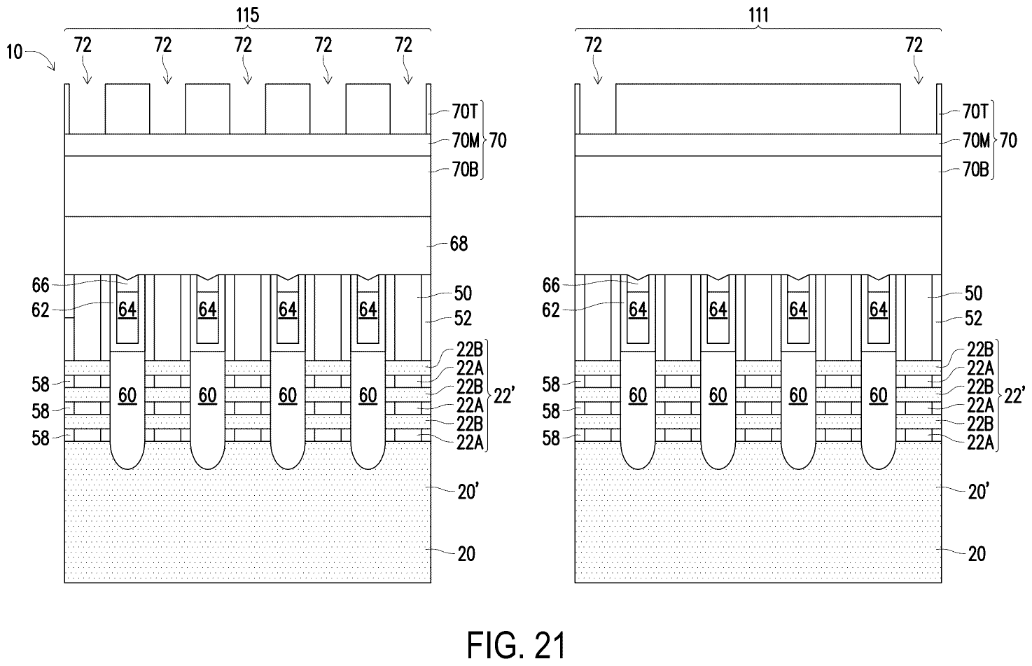

FIGS. 20, 21, 22, and 23 illustrate the formation of fin isolation regions 84 (FIG. 21) in dummy gate stack 50 and the underlying isolation regions 86 (FIG. 23), which regions cut through and electrically isolate neighboring protruding fins. The isolation regions 84 may also be referred to as Cut-Poly on Diffusion Edge (CPODE) regions since the formation process involves the cutting of polysilicon dummy gate electrode on the edge of active regions. FIG. 21 illustrates the deposition of hard mask 68 and etching mask 70. In accordance with some embodiments, hard mask 68 is formed of or comprises silicon nitride, silicon oxynitride, or the like. In accordance with some embodiments, etching mask 70 is a tri-layer etching mask, which includes bottom layer 70B, middle layer 70M, and top layer 70T. Bottom layer 70B may be formed of a cross-linked photoresist. Middle layer 70M may be formed of an inorganic dielectric material. Top layer 70T is formed of a patterned photoresist, which has trenches 72 patterned therein.

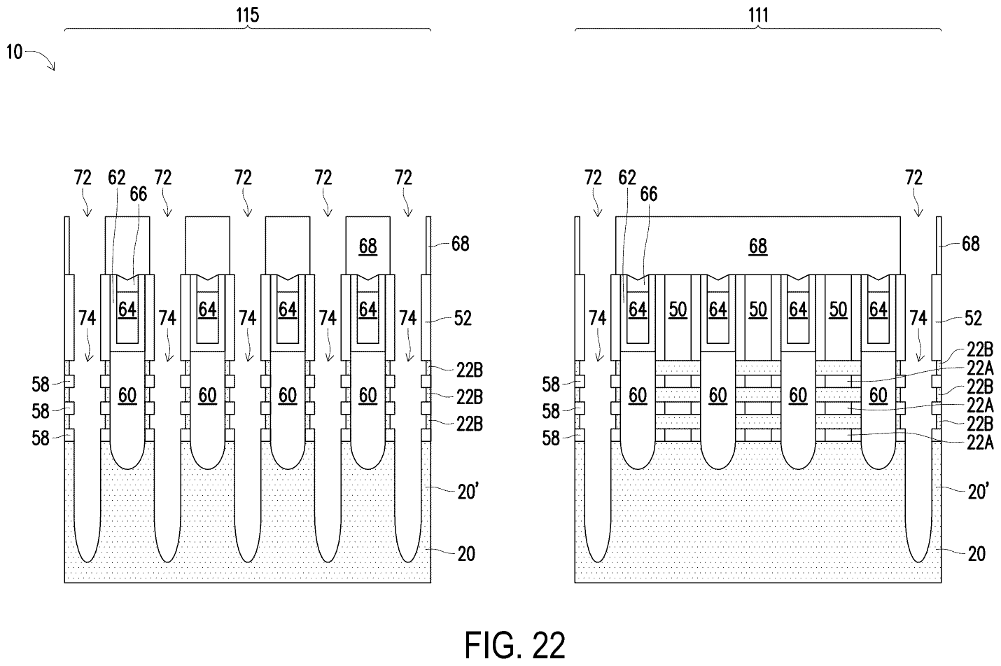

In FIG. 22, trenches 72 and 74 are etched, in accordance with some embodiments. As shown in FIG. 22, the etching of the trenches 72 and 74 removes first layers 22A between inner spacers 58 and removes second layers 22B. In some embodiments, top layer 70T (see FIG. 21) is used as an etching mask to etch middle layer 70M and bottom layer 70B. During the etching process, top layer 70T (and possibly middle layer 70M) may be consumed, leaving a patterned bottom layer 70B. In this manner, the trenches 72 may be transferred from top layer 70T to bottom layer 70B. The remaining etching mask 70 is then used to etch hard mask 68, such that trenches 72 are further transferred into hard mask 68. The remaining etching mask 70 is then removed, with the patterned hard mask 68 remaining. The patterned hard mask 68 is then used as an etching mask to etch the underlying structure to form trenches 72 and 74. First, gate stack 50 is etched, such that trench 72 further extends down into gate stack 50. The portion of trench 72 in gate stack 50 is also referred to a through-gate trench. The etching process is anisotropic, such that the trench 72 may have substantially vertical sidewalls. The etching of dummy gate electrode layer 46, when formed of polysilicon or amorphous silicon, may be performed using fluorine (F₂), Chlorine (Cl₂), hydrogen chloride (HCl), hydrogen bromide (HBr), Bromine (Br₂), C₂F₆, CF₄, SO₂, the like, or combinations thereof.

After the etching of the dummy gate electrode layer 46, the dummy gate dielectric 44 and any native oxide formed on the surfaces of multilayer stacks 22′ are removed through an etching process. The corresponding process may also be referred to as a dielectric break-through process. In accordance with some embodiments, the etching may be performed using CF₄, Ar, and/or the like, and the etching may have a low selectivity. After the dielectric-break through process, high-k dielectric regions 38 are revealed, and multilayer stacks 22′ are also revealed to the trenches 72. Next, multilayer stacks 22′ are etched and semiconductor strips 20′ are etched. As shown in FIG. 20, the underlying bulk portion of substrate 20 underlying STI regions 30 are also etched. In accordance with some embodiments, the etching process includes a selective etch that has a high etching selectivity between semiconductor materials and dielectric materials. Accordingly, high-k dielectric regions 38, inner spacers 58, STI regions 30, etc., which are revealed in the etching process, are not etched. Trenches 74, which are also referred to as through-gate trenches, are thus formed. Trenches 74 may be considered part of trenches 72, in some cases.

In accordance with some embodiments, the etching of multilayer stacks 22′, semiconductor strips 20′, and the underlying bulk portion of substrate 20 are performed using HBr, O₂, and/or Ar. In the etching of semiconductor strips 20′ and the underlying bulk portion of substrate 20, CO₂ may also be added in addition to O₂ or replacing O₂. The etching processes may also be performed using other etching gases such as F₂, Cl₂, HCl, HBr, Br₂, C₂F₆, CF₄, SO₂, O₂, CH₂F₂, the like, or combinations thereof. In some embodiments, the etching is performed using plasma etching, which may be performed with a bias power applied to achieve anisotropic etching.

FIG. 23 illustrates a deposition process that fills trenches 72 and 74 and forms isolation regions 86, in accordance with some embodiments. The deposition process may deposit one or more dielectric layers within the trenches 72/74. In some embodiments, the dielectric layers include a dielectric liner and a dielectric fill layer (not separately illustrated). The dielectric liner may be formed of or comprise silicon oxide. The dielectric fill layer may be formed of or comprise silicon nitride. Other materials such as silicon carbide, silicon oxynitride, silicon carbonitride, silicon oxycarbonitride, or the like may also be used to form the dielectric layers. In some embodiments, a planarization process (e.g., a CMP process, grinding process, or the like) may be performed to remove excess dielectric layer material, with remaining portions of the dielectric layers forming the isolation regions 86. In some embodiments, the planarization process removes remaining portions of the hard mask 68.

In some cases, forming isolation regions 86 in the outer buffer region 115 allows the topography and composition of the outer buffer region 115 to be similar to those of the device region 111. This can allow for the outer buffer region 115 to have more planar topography, which can allow for a smaller outer buffer region 115 and also improve processing of the device die 100. For example, a more planar outer buffer region 115 can reduce the risk of topography-related processing problems. In this manner, yield can be improved. Additionally, as described previously, the formation of epitaxial source/drain regions 60 in the outer buffer region 115 can eliminate loading effects due to the formation of epitaxial source/drain regions 60 and also can reduce stresses caused by the seal ring 112 or the singulation process. Additionally, isolation regions 86 and epitaxial source/drain regions 60 may be formed in the outer buffer region 115 without additional process steps being required.

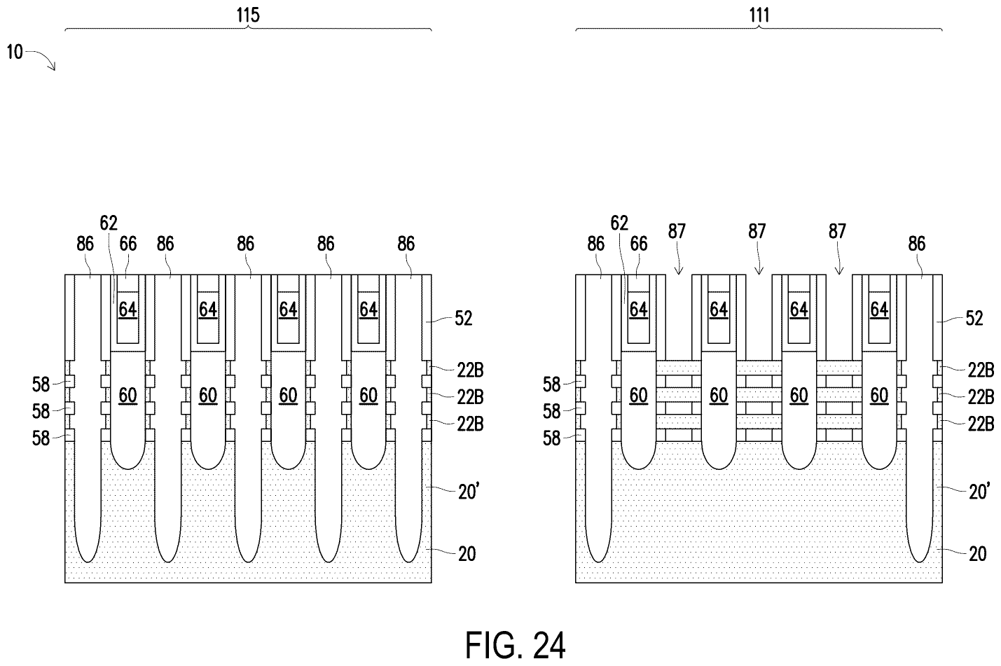

In FIG. 24, gate stacks 50 and sacrificial layers 22A in the device region 111 are removed, in accordance with some embodiments. In some embodiments, gate stacks 50 are removed by an anisotropic dry etch process that selectively etches the materials of the gate stacks 50. The sacrificial layers 22A may then be removed by performing an isotropic etching process such as wet etching or the like using etchants which are selective to the materials of the sacrificial layers 22A. The etching processes form recesses 87 that expose surfaces of the nanostructures 22B and which may surround the nanostructures 22B.

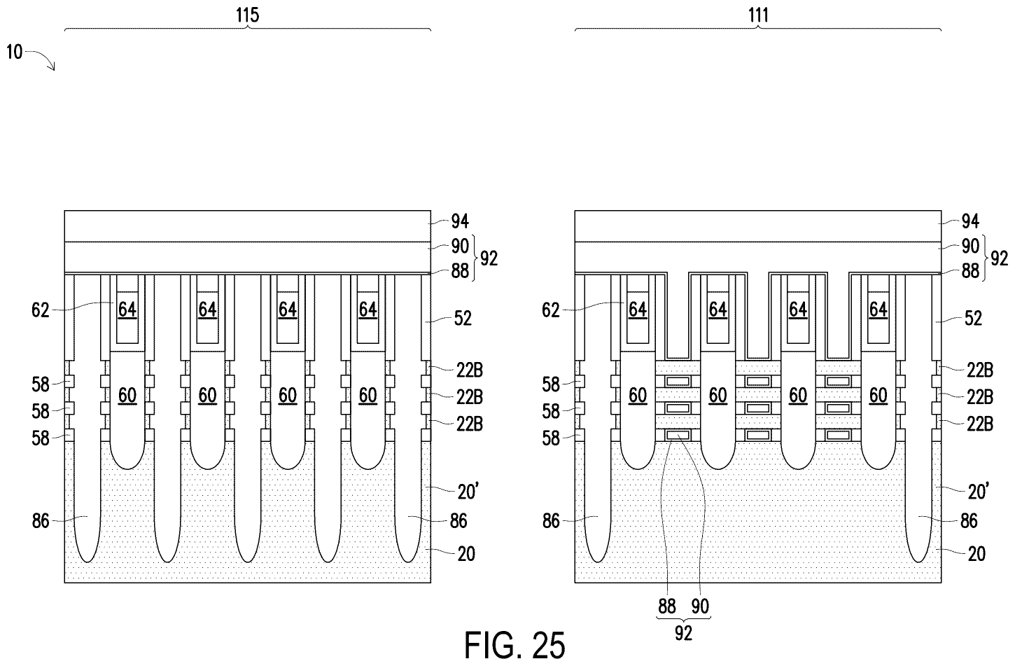

In FIG. 25, gate dielectrics 88 and gate electrodes 90 are formed for replacement gate stacks 92. The gate dielectrics 88 are deposited conformally in the recesses 87. In accordance with some embodiments, the gate dielectrics 88 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectrics 88 include a high-k dielectric material, and in these embodiments, the gate dielectrics 88 may have a k value greater than about 7.0, and may include a metal oxide or a silicate of hafnium, aluminum, zirconium, lanthanum, manganese, barium, titanium, lead, and combinations thereof. The formation methods of the gate dielectrics 88 may include molecular-beam deposition (MBD), ALD, PECVD, and the like.

The gate electrodes 90 are deposited over the gate dielectrics 88, respectively, and fill the remaining portions of the recesses 87. The gate electrodes 90 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 90 are illustrated in FIG. 25, the gate electrodes 90 may comprise any number of liner layers, any number of work function tuning layers, and a fill material. Any combination of the layers which make up the gate electrodes 90 may be deposited between adjacent ones of the nanostructures 22B. The gate dielectrics 88 and the gate electrodes 90 together may be considered replacement gate stacks 92 or replacement gate structures 92.

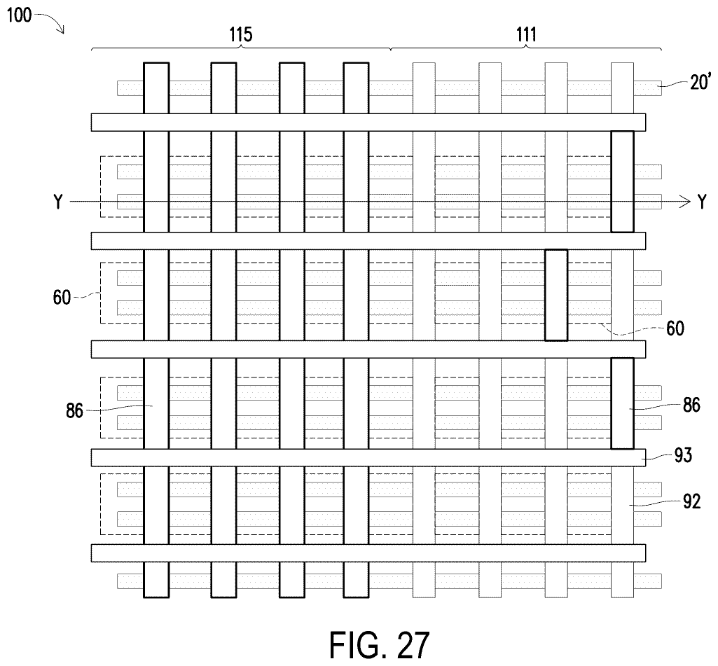

The replacement gate stacks 92 at least partially surround nanostructures 22B, and these nanostructures 22B act as the channel regions of the resulting NSFETs of the device region 111. As shown in FIG. 25, the presence of the isolation regions 86 in the outer buffer region 115 blocks the replacement gate stacks 92 from being formed on the nanostructures 22B in that region. Similarly, the isolation regions 86 in the device region 111 blocks the replacement gate stacks 92 from being formed on some of the nanostructures 22B. A dielectric layer 94, which may include an etch stop layer, may be formed over replacement gate stacks 92. In some embodiments, portions of the replacement gate stacks 92 may be removed and replaced by a dielectric “cut material” (see cut material 93 in FIG. 27) to isolate adjacent replacement gate structures 92. The cut material may be, for example, an oxide, a nitride, a material similar to those described for the dielectric regions 86, or the like. In some embodiments, portions of the dielectric regions 86 are also removed and replaced by the cut material.

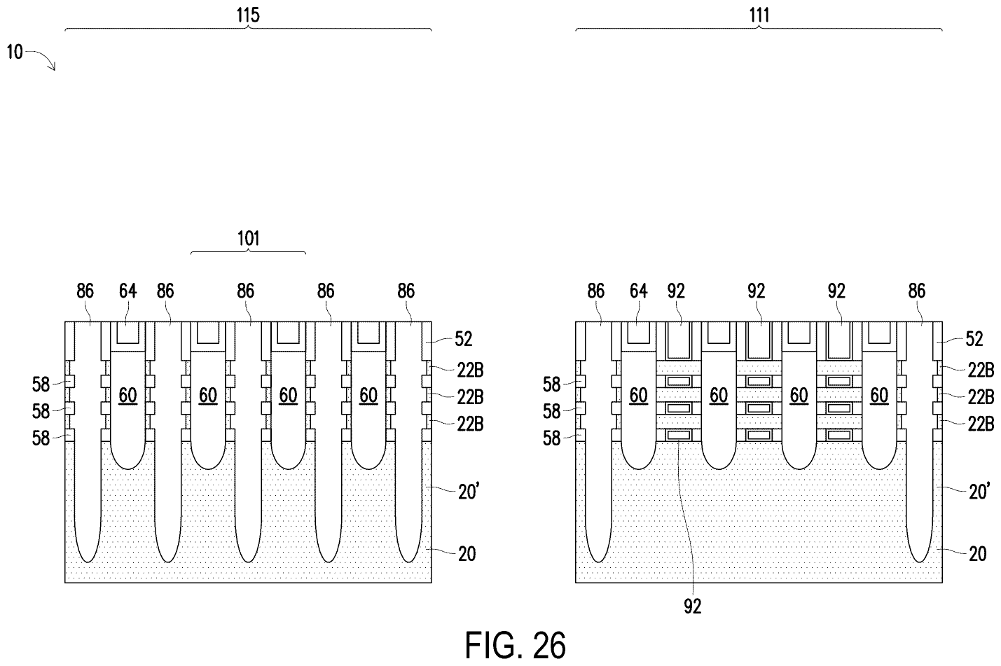

In FIG. 26, a planarization process is performed to remove excess material of the replacement gate stacks 92. The planarization process may include, for example, a CMP process, a grinding process, or the like. In some embodiments, the planarization process removes hard masks 66. In this manner, NSFETs may be formed in the device region 111. In some cases, the structures in the outer buffer region 115 may be considered dummy devices, an example of which is indicated by dummy device 101 in FIG. 26.

FIG. 27 illustrates a plan view of an outer buffer region 115 and a device region 111, in accordance with some embodiments. The outer buffer region 115 and the device region 111 shown in FIG. 27 may be similar to those shown in FIG. 26. FIG. 27 shows the outer buffer region 115 as being adjacent the device region 111, but in other cases the buffer region 115 may be separated from the device region 111 by a seal ring region 113, an inner buffer region 114, or the like. As shown in FIG. 27, in the outer buffer region 115, the replacement gate stacks 92 are not formed, and isolation regions 86 are formed instead. In this manner, the outer buffer region 115 may be a metal-free region, in some embodiments. In some cases, isolation regions 86 may also be formed in the device region 111, as shown. FIG. 27 also shows cut material 93 separating adjacent replacement gate stacks 92 in the device region 111. In some embodiments, the cut material 93 may also separate isolation regions 86 in the outer buffer region 115. In other embodiments, the cut material may not be formed in the outer buffer region 115.

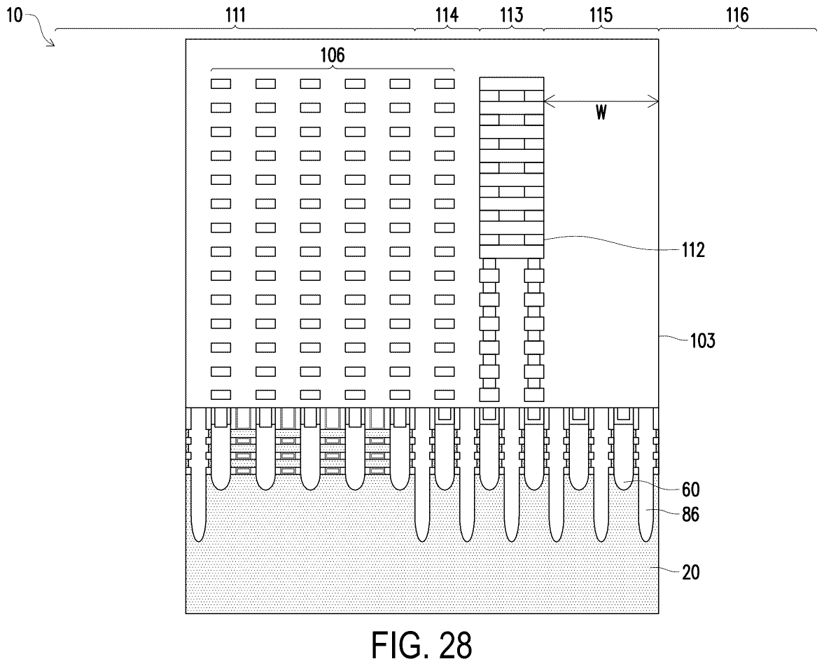

FIG. 28 illustrates a cross-sectional view of a device region 111, inner buffer region 114, seal ring region 113, outer buffer region 115, and scribe region 116 of a wafer 10, in accordance with some embodiments. Following FIG. 27, an interconnect structure 106 is formed in the device region 111 and a seal ring 112 is formed in the seal ring region 113, in accordance with some embodiments. The interconnect structure 106 and the seal ring 112 may be formed, for example, by forming a plurality of metallization layers (not individually labeled) in a plurality of insulating layers, such as Inter-Metal Dielectric (IMD) layers 103. The metallization layers comprise conductive features such as vias, contacts, and/or lines embedded in the IMD layers 103. The metallization layers may be formed using suitable techniques, such as using a damascene process, a dual damascene process, or the like. The interconnect structure 106 interconnects the devices in the device region 111 (e.g., NSFETs and/or other devices) to form integrated circuits. The seal ring 112 may be formed using the same process steps as the interconnect structure 106. The seal ring 112, interconnect structure 106, and the metallization layers thereof shown in FIG. 28 are examples, and other configurations or arrangements are possible.

In some embodiments, the inner buffer region 114 may include dummy devices similar to the dummy devices 101 of the outer buffer region 115. In other embodiments, the inner buffer region 114 may include dummy devices similar to the devices of the device region 111. The inner buffer region 114 may or may not include dummy conductive features. As shown in FIG. 28, the metallization layers are not formed in the outer buffer region 115 to facilitate plasma dicing. In some embodiments, the outer buffer region 115 may have a width W in the range of about 5 μm to about 25 μm, though other widths are possible. FIG. 28 is an illustrative example, and the interconnect structure 106, seal ring 112, inner buffer region 114, or outer buffer region 115 may have different dimensions, numbers of features, configurations, or arrangements than shown.

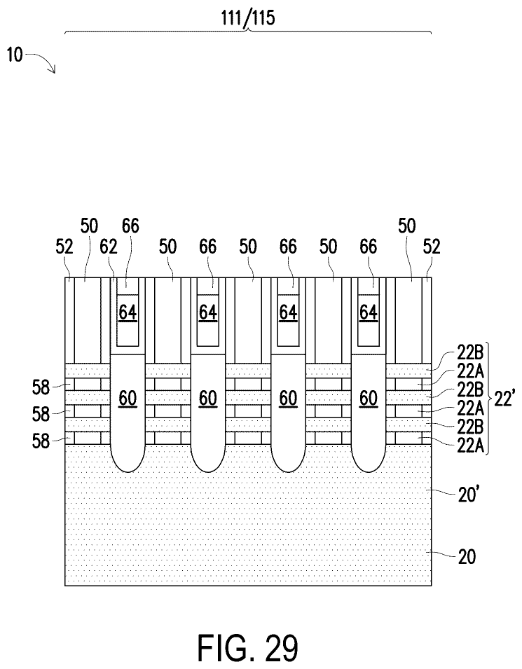

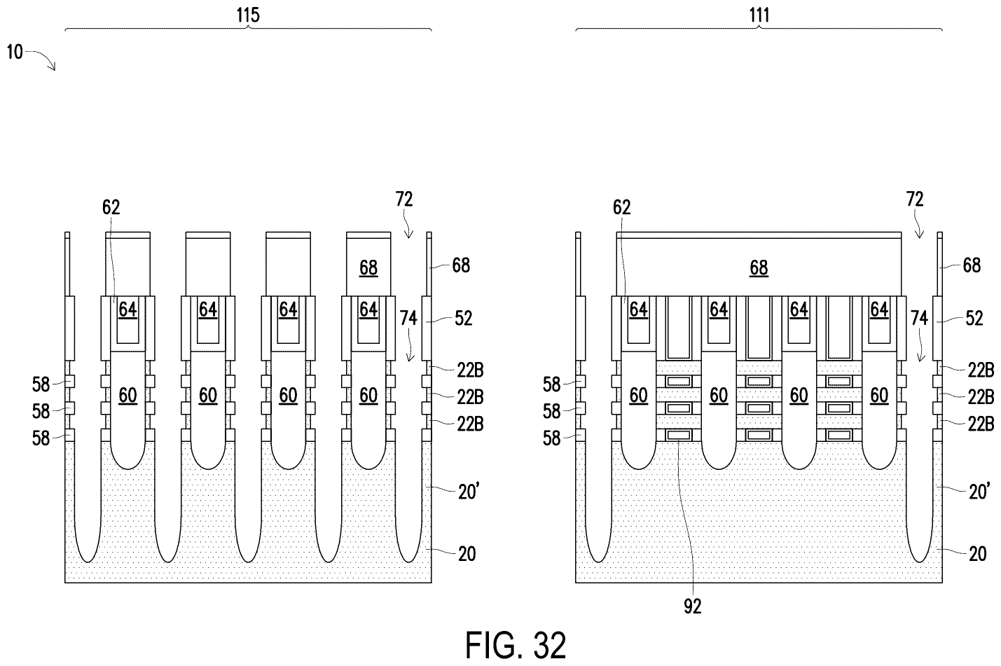

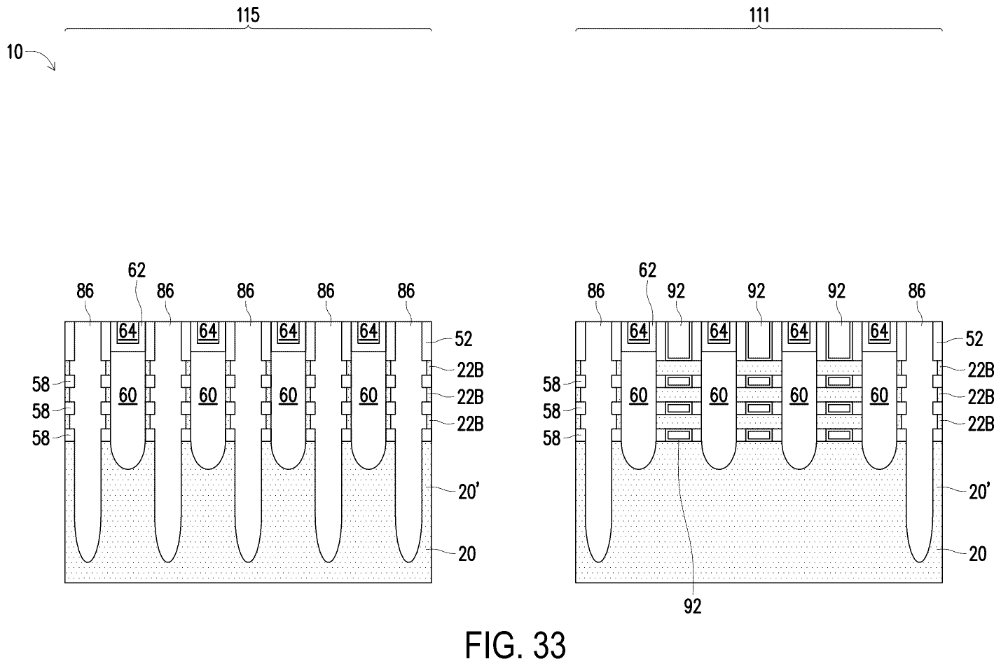

FIGS. 29 through 33 illustrate intermediate steps in the formation of isolation regions 86, in accordance with some embodiments. The process shown in FIGS. 29-33 is similar to the process described previously for FIGS. 19-26, except that the replacement gate stacks 92 are formed before the isolation regions 86 are formed. FIGS. 29-33 are cross-sectional views similar to those of FIGS. 20-26. FIGS. 29, 30, and 31 show cross-sectional views of a region that could be either a outer buffer region 115 or a device region 111, and FIGS. 32 and 33 each show cross-sectional views of a buffer region 115 and a device region 111. The processing steps shown for the buffer region 115 may also be performed for the inner buffer region 114 and/or the seal ring region 113, in some embodiments.

FIG. 29 shows a cross-sectional view of a structure similar to that shown in FIG. 20, which may be formed using a process similar to that described for FIGS. 3-20. For example, the structure of FIG. 29 includes epitaxial source/drain regions 60 and gate stacks 50 formed over multilayer stacks 22′.

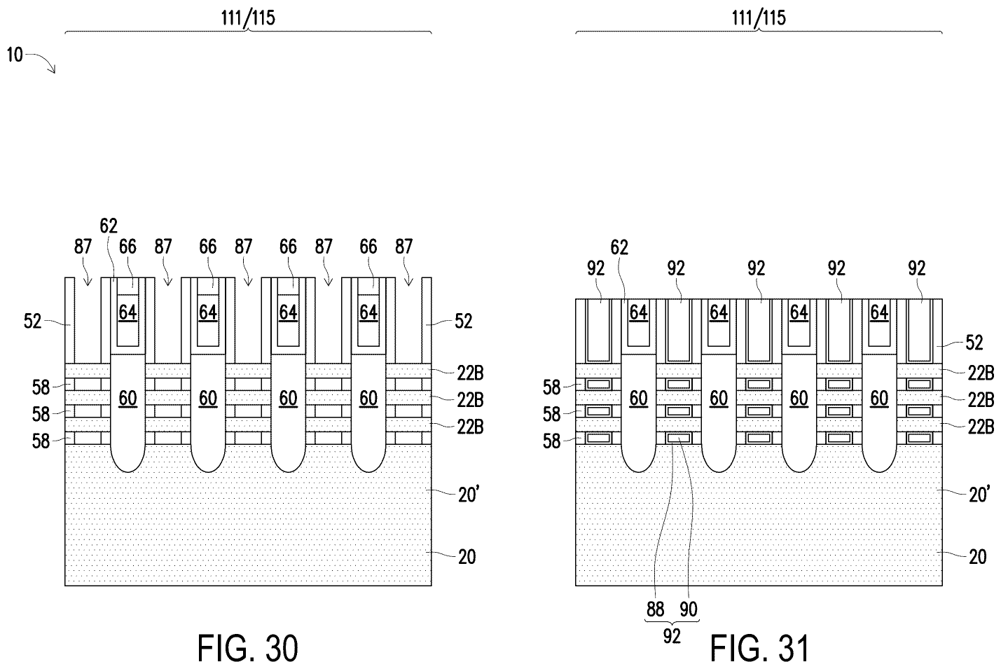

In FIG. 30, one or more etching processes are performed to remove the gate stacks 50 and the first layers 22A, forming recesses 87. The etching processes and recesses 87 may be similar to those described previously for FIG. 24. For example, the gate stacks 50 and the first layers 22A may be selectively removed to form nanostructures 22B.

In FIG. 31, gate dielectrics 88 and gate electrodes 90 are deposited in the recesses to form replacement gate stacks 92, in accordance with some embodiments. The gate dielectrics 88 and gate electrodes 90 may be formed using materials or techniques similar to those described previously for FIG. 25. After depositing the materials of the gate dielectrics 88 and the gate electrodes 90, a planarization process may be performed, similar to the process described for FIG. 26. In some cases, the structure shown in FIG. 31 may be similar to the structure of the device region 111 shown in FIG. 26.

In FIG. 32, a hard mask 68 is formed over the structure and trenches 72/74 are etched, in accordance with some embodiments. The hard mask 68 may be formed over the outer buffer region 115 and device region 111 and patterned, similar to the steps described for FIGS. 21-22. One or more etching processes may then be performed to form trenches 72 and 74, which may be similar to the step described for FIG. 22. For example, the etching process(es) remove the gate stacks 50 and the multilayer stacks 22′ in the outer buffer region 115.

In FIG. 33, a deposition process is performed to fill trenches 72 and 74 and form isolation regions 86, in accordance with some embodiments. The deposition process may be similar to that described previously for FIG. 23. For example, the deposition process may deposit one or more dielectric layers within the trenches 72/74. A planarization process, such as a CMP process or the like, make be performed to remove excess dielectric layer material.

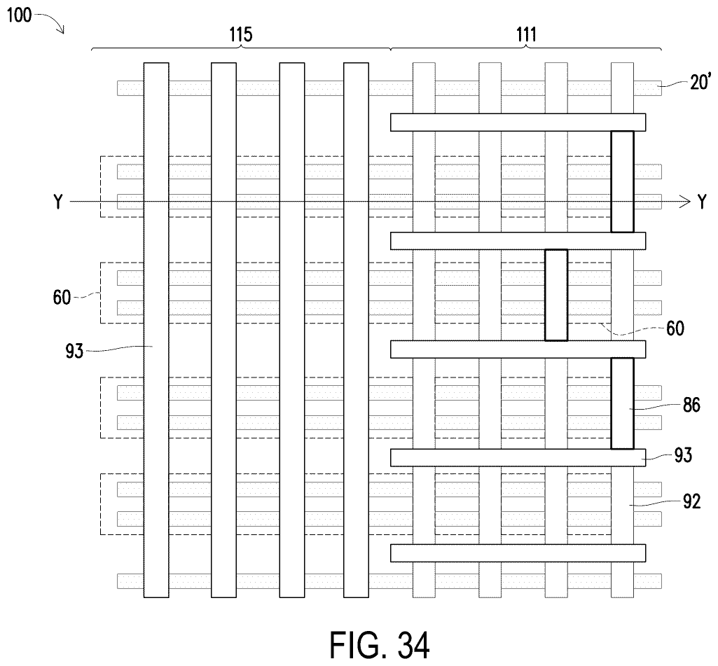

FIG. 34 illustrates a plan view of an outer buffer region 115 and a device region 111, in accordance with some embodiments. The structure shown in FIG. 34 is similar to the structure shown in FIG. 27, except that the isolation regions 86 in the outer buffer region 115 are formed of the cut material 93. FIG. 34 shows the outer buffer region 115 as being adjacent the device region 111, but in other cases the buffer region 115 may be separated from the device region 111 by a seal ring region 113, an inner buffer region 114, or the like. As shown in FIG. 34 in the outer buffer region 115, the replacement gate stacks 92 are not formed. In this manner, the outer buffer region 115 may be a metal-free region, in some embodiments. In some cases, the cut material 93 in the outer buffer region 115 may be formed using the same process steps used to form the cut material 93 in the device region 111. In some embodiments, isolation regions 86 may be formed in the device region 111 and not in the outer buffer regions 115.

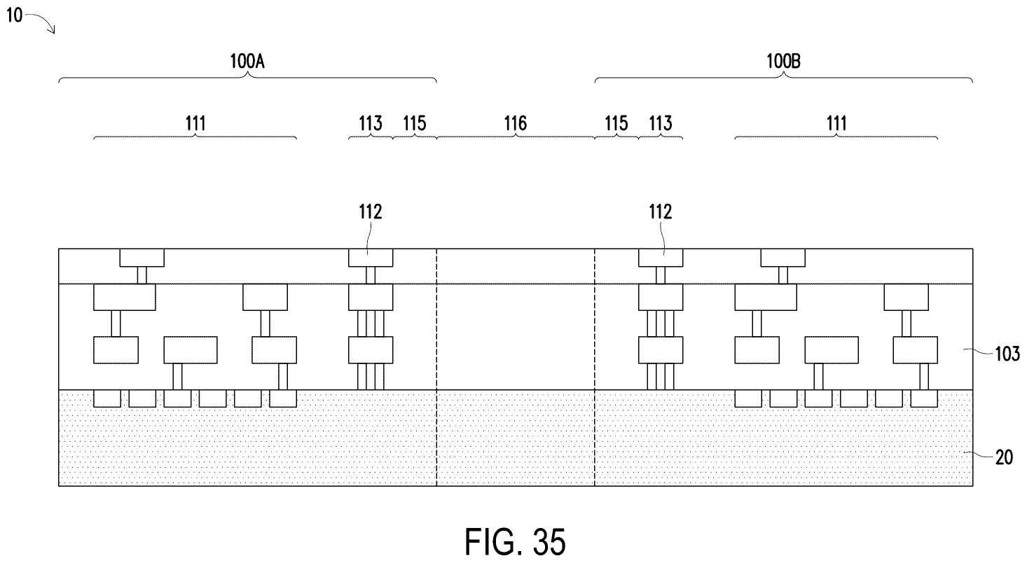

FIGS. 35, 36, and 37 illustrate intermediate steps in the singulation of two device dies 100A-B of a wafer 10, in accordance with some embodiments. The device dies 100A-B and wafer 10 may be similar to those described elsewhere herein. For example, the device dies 100 each comprise a device region 111 and a seal ring 112, and each seal ring 112 is separated from a scribe region 116 by an outer buffer region 115. FIG. 35 shows a cross-sectional view of a first device die 100A and a second device die 100B of a wafer 10. The first device die 100A is separated from the second device die 100B by a scribe region 116, similar to FIG. 2.

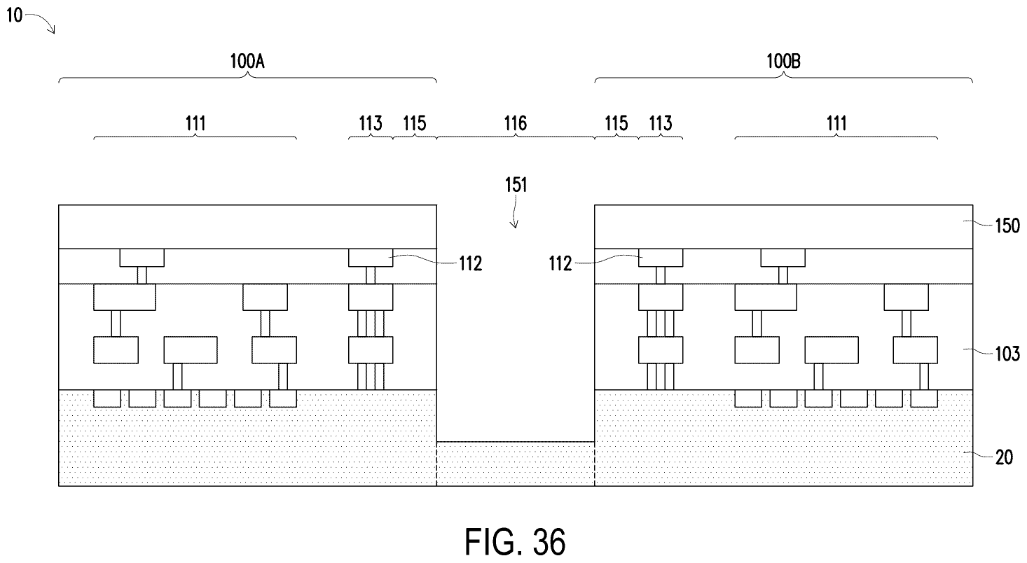

In FIG. 36, a patterned mask 150, such as patterned photoresist layer, is formed over the wafer 10. The openings in the pattern of the patterned mask 150 correspond to dicing paths of the singulation process. Next, a dicing process, such as a plasma dicing process, is performed along the dicing paths in the scribe regions 116 to form recesses 151 (e.g., trenches in a top view). The plasma dicing process etches portions of the wafer 10 exposed by the openings in the patterned mask 150. As illustrated in FIG. 36, the recess 151 extends through the dielectric layers 103 and into the substrate 20. A bottom of the recess 151 is between an upper surface and a lower surface of the substrate 20, in some embodiments. In other words, the recess 151 extends into, but not through, the substrate 20. In other embodiments, the recess 151 extends fully through the substrate 20. In some embodiments, the plasma dicing process removes portions of the outer buffer regions 115 such that the recess 151 extends into the outer buffer regions 115. The presence of the metal-free outer buffer regions 115 can improve the plasma dicing process and reduce the risk of damage to the device dies 100A-B, in some cases.

In some embodiments, the plasma dicing comprises a dry plasma process such as Deep Reactive Ion Etching (DRIE) process or the like. The plasma dicing process may be an etching process that can etch narrow trenches into the substrate 20 to separate individual dies. Issues with dicing using a blade, such as die chipping or cracking, may be avoided by the plasma dicing process, thereby improving the yield of the manufacturing process. Unlike dicing using a blade, plasma dicing avoids or reduces damage to the wafer surface and/or sidewalls, resulting in greater die strengths, improved device reliability, and increased device lifetime. Due to the narrower dicing path of the plasma dicing, the scribe regions 116 may be made narrower, thus allowing for more device dies 100 to be formed in the wafer 10 to reduce production cost per die. In addition, plasma dicing may be performed along multiple dicing paths simultaneously, thus increasing the throughput of the manufacturing process. Furthermore, by defining the shape of the openings in the patterned mask 150, non-rectangular die shapes are easily achieved using plasma dicing.

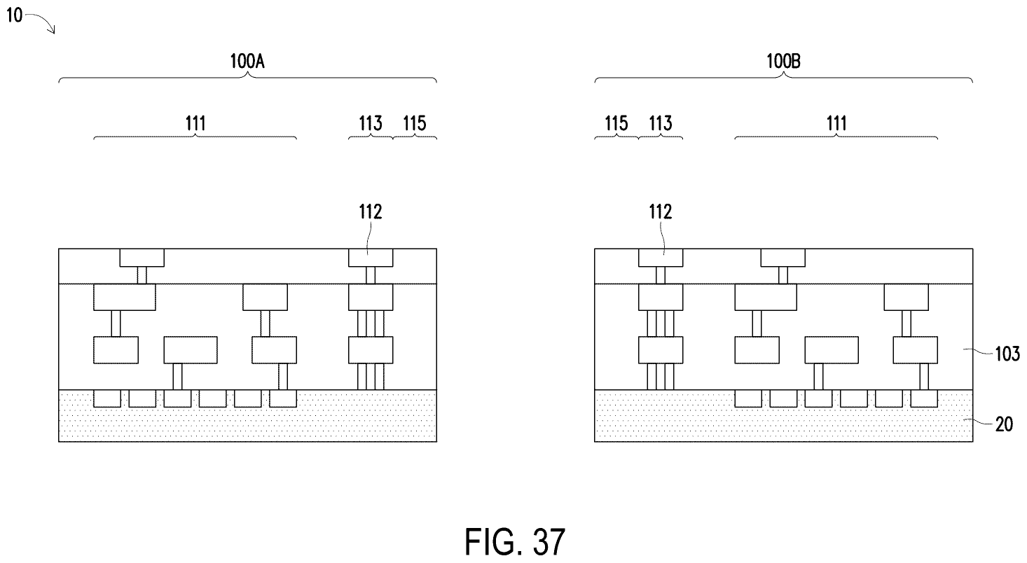

Next, in FIG. 37, the thickness of the substrate 20 is reduced. A grinding process, such as CMP or the like, may be performed on the backside of the substrate 20 to reduce the thickness of the substrate 20. In some embodiments, the grinding process stops when the recesses 151 extends through the (thinned) substrate 20, therefore separating the wafer 10 into a plurality of individual device dies 100A-B.

The embodiments described herein may present advantages. By forming isolation regions in a buffer region between a seal ring and a scribe region, the topography and planarity of the buffer region may be improved, which can improve processing and improve yield. In some cases, this can also improve the planarity or processing of neighboring regions such as those for the seal ring or the scribe region. Forming isolation regions also allows the seal ring to be formed closer to the scribe region without significant reduction in yield or performance. In other words, a small buffer region may be formed. Thus, device density may be improved. Further, forming epitaxial source/drain regions in the buffer region can reduce stress in the structure from the seal ring or from singulation, which can further improve yield and device performance. In some cases, the isolation regions and/or epitaxial source/drain regions may be formed without additional processing steps. The buffer regions maybe formed without metal features, which can improve plasma dicing of the scribe region.

In an embodiment of the present disclosure, a method includes forming first nanostructures over a first region of a substrate; forming second nanostructures over a second region of the substrate; forming first gate structures around the first nanostructures; replacing the second nanostructures with isolation regions; and forming a seal ring over the substrate, wherein the seal ring is between the first region and the second region. In an embodiment, the method includes replacing at least one first nanostructure with an isolation region. In an embodiment, replacing the second nanostructures includes: forming a dummy gate structures around the second nanostructures; performing an etching process to form recesses, wherein forming the recesses removes the dummy gate structures and the second nanostructures; and filling the recesses with a dielectric material to form the isolation regions. In an embodiment, the first gate structures are formed before replacing the second nanostructures. In an embodiment, the method includes forming first epitaxial source/drain regions adjacent the first nanostructures and second epitaxial source/drain regions adjacent the second nanostructures. In an embodiment, the second region separates the seal ring from a scribe region. In an embodiment, the seal ring is formed over at least one isolation region. In an embodiment, the method includes forming an interconnect structure over the first nanostructures, wherein the second region is free of the interconnect structure. In an embodiment, the second region has a width in the range of 5 μm to 25 μm.

In an embodiment of the present disclosure, a method includes forming a seal ring over a substrate, which includes forming conductive features within insulating layers; and forming a buffer region encircling the seal ring, wherein forming the buffer region includes: forming a stack of first nanostructures over a substrate; forming an epitaxial source/drain region adjacent the stack of first nanostructures; forming a dummy gate structure over the stack of first nanostructures; forming a first recess extending through the dummy gate structure and the stack of nanostructures, wherein the recess extends deeper than the epitaxial source/drain region; filling the first recess with a dielectric material; and forming the insulating layers over the dielectric material. In an embodiment, the buffer region is free of the conductive features. In an embodiment, the method includes forming a scribe region encircling the buffer region and performing a plasma dicing process on the scribe region. In an embodiment, the plasma dicing process removes portions of the buffer region. In an embodiment, the method includes forming second nanostructures over the substrate, wherein the seal ring encircles the second nanostructures; forming a gate structure over the second nanostructures; removing a portion of the gate structure to form a second recess; and filling the second recess with the dielectric material. In an embodiment, the dielectric material is different from the material of the insulating layers.

In an embodiment of the present disclosure, a structure includes devices on a substrate; a seal ring encircling the devices; and a buffer region separating the seal ring from the scribe region, wherein the buffer region includes: epitaxial regions on the substrate; and isolation regions extending into the substrate, wherein each isolation region is sandwiched between epitaxial regions. In an embodiment, the devices include nanostructures, wherein each nanostructure is sandwiched between epitaxial regions. In an embodiment, the buffer region includes dummy devices. In an embodiment, the buffer region is free of metal. In an embodiment, the structure includes a scribe region encircling the seal ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a plurality of epitaxial regions in a first region of a substrate and in a second region of the substrate, wherein the second region of the substrate extends from the first region of the substrate to an edge of the substrate;
a plurality of nanostructures between neighboring epitaxial regions in the first region of the substrate;
a plurality of first isolation regions between neighboring epitaxial regions in the second region of the substrate; and
a seal structure over at least one epitaxial region in the second region of the substrate.

2. The structure of claim 1, wherein a distance between the seal structure and the edge of the substrate is in the range of 5 μm to 25 μm.

3. The structure of claim 1, wherein the second region surrounds the first region.

4. The structure of claim 1 further comprising a second isolation region between two neighboring epitaxial regions in the first region of the substrate.

5. The structure of claim 1, wherein the seal structure extends over at least one first isolation region in the second region of the substrate.

6. The structure of claim 1, wherein the second region of the substrate is free of nanostructures.

7. The structure of claim 1 further comprising a plurality of semiconductor fins in the first region of the substrate and in the second region of the substrate.

8. The structure of claim 7, wherein at least one semiconductor fin extends from the first region of the substrate to the second region of the substrate.

9. The structure of claim 1, wherein the second region of the substrate is free of metal features.

10. A structure comprising:
a semiconductor fin over a substrate;
a first source/drain region in the semiconductor fin;
a second source/drain region in the semiconductor fin;
a nanostructure adjacent the first source/drain region;
a first isolation structure in the semiconductor fin adjacent the second source/drain region; and
a seal ring between the first source/drain region and the second source/drain region.

11. The structure of claim 10, wherein the seal ring is over a third source/drain region in the semiconductor fin.

12. The structure of claim 10, wherein the second source/drain region is a dummy source/drain region.

13. The structure of claim 10 further comprising a second isolation structure adjacent the nanostructure.

14. The structure of claim 10, wherein the second source/drain region is closer to an edge of the substrate than the first source/drain region.

15. The structure of claim 10, wherein the seal ring surrounds the first source/drain region.

16. The structure of claim 10, wherein the first isolation structure protrudes into the substrate.

17. A method comprising:
forming a plurality of first dummy gate structures and a plurality of second dummy gate structures over a substrate, wherein the plurality of second dummy gate structures are between the plurality of first dummy gate structures and a scribe region of the substrate;
replacing the plurality of first dummy gate structures with a plurality of first replacement gate structures and replacing the plurality of second dummy gate structures with a plurality of second replacement gate structures;
removing the plurality of second replacement gate structures to form a plurality of recesses;
forming a plurality of isolation structures in the plurality of recesses; and
performing a singulation process on the scribe region.

18. The method of claim 17 further comprising a plurality of nanostructures over the substrate, wherein the plurality of first dummy gate structures and the plurality of second dummy gate structures are formed around the plurality of nanostructures.

19. The method of claim 17, wherein the singulation process comprises a plasma dicing process.

20. The method of claim 17 further comprising forming a seal ring over the plurality of isolation structures.
